(19) United States
(12) Patent Application Publication
(10) Pub. No.: US 2025/0282672 A1
(43) Pub. Date: Sep. 11, 2025

(54) HIGH YOUNG'S MODULUS, LITHIUM OXIDE-CONTAINING GLASSES

(71) Applicant: CORNING INCORPORATED, CORNING, NY (US)

(72) Inventor: Alexandra Lai Ching Kao Andrews Mitchell, Ithaca, NY (US)

(21) Appl. No.: 19/063,841

(22) Filed: Feb. 26, 2025

Related U.S. Application Data
(60) Provisional application No. 63/562,930, filed on Mar. 8, 2024.

(51) Int. Cl. C03C 3/085; C03C 21/00; H05K 5/03

(52) U.S. Cl. CPC C03C 3/085; C03C 21/001; H05K 5/03

(57) ABSTRACT

A glass comprising 62.5-68 mol. % SiO₂; 9.5-16 mol. % Al₂O₃; 12-16 mol. % MgO; 8-11.2 mol. % Li₂O; and less than 0.6 mol. % ZrO₂; wherein R₂O/Al₂O₃ is at least 0.8, amounts are in mol. %, and R₂O is a total amount of Li₂O, Na₂O, K₂O, Rb₂O, and Cs₂O in the glass. A glass-based article comprising a compressive stress layer extending from a surface of the glass-based article to a depth of compression; a central tension region; and a composition at a center of the glass-based article comprising the glass. A method for ion-exchanging a glass-based substrate, the method comprising ion-exchanging the glass-based substrate in a first molten salt bath to form a glass-based article wherein the glass-based article comprises a compressive stress layer extending from a surface of the glass-based article to a depth of compression, the glass-based article comprises a central tension region, and the glass-based substrate comprises the glass.

### CROSS-REFERENCE TO RELATED APPLICATIONS

This application claims the benefit of priority of U.S. Provisional Patent Application Ser. No. 63/562,930, filed on Mar. 8, 2024, the content of which is relied upon and incorporated herein by reference in its entirety.

### FIELD

The disclosure relates generally to glasses and glass-based articles having a high Young's modulus, and more particularly to aluminosilicate glasses and glass-based articles which comprise lithium oxide and magnesium oxide and have a high Young's modulus. Such articles are suitable for various uses, including as a cover glass and/or housing for electronic devices.

### BACKGROUND

The mobile nature of portable devices, such as smart phones, tablets, portable media players, personal computers, and cameras, makes these devices particularly vulnerable to accidental dropping on hard surfaces, such as the ground. These devices typically incorporate cover glasses and/or glass-based housings, which may become damaged upon impact with hard surfaces and/or when experiencing flexural stresses. In many of these devices, the cover glasses function as display covers, and may incorporate touch functionality, such that use of the devices is negatively impacted when the cover glasses are damaged. Similarly, when housings are made of glass-based articles, negative results may occur when the housing is damaged.

Thin glasses are desirable for various reasons, such as to reduce material costs and to make a device with a thinner overall profile. However, thinner glasses generally are more susceptible to flexural and sharp contact failures.

Glasses may be made stronger, for example, by ion-exchanging the glasses to introduce a compressive stress layer. While such a solution provides a stronger glass more resistant to flexural failure, the glass is still vulnerable to dynamic sharp contacts.

Thus, there remains a need in the art for glasses and glass-based articles that have desirable properties, including desired mechanical properties such as a high Young's modulus.

### SUMMARY

The disclosure relates, in various aspects, to a glass, comprising:
62.5-68 mol. % SiO₂;
9.5-16 mol. % Al₂O₃;
12-16 mol. % MgO;
8-11.2 mol. % Li₂O; and
less than 0.6 mol. % ZrO₂;
wherein R₂O/Al₂O₃ is at least 0.8, amounts are in mol. %, and R₂O is a total amount of Li₂O, Na₂O, K₂O, Rb₂O, and Cs₂O in the glass.

The disclosure also relates, in various aspects, to a method for ion-exchanging a glass-based substrate, the method comprising:
ion-exchanging the glass-based substrate in a first molten salt bath to form a glass-based article,
wherein the glass-based article comprises a compressive stress layer extending from a surface of the glass-based article to a depth of compression, the glass-based article comprises a central tension region, and the glass-based substrate comprises a glass composition disclosed herein.

The disclosure relates, in various aspects, to a glass-based article, comprising:
a compressive stress layer extending from a surface of the glass-based article to a depth of compression;
a central tension region; and
a composition at a center of the glass-based article comprising:
   62.5-68 mol. % SiO₂;
   9.5-16 mol. % Al₂O₃;
   12-16 mol. % MgO;
   8-11.2 mol. % Li₂O; and
   less than 0.6 mol. % ZrO₂;
   wherein R₂O/Al₂O₃ is at least 0.8, amounts are in mol. %, and R₂O is a total amount of Li₂O, Na₂O, K₂O, Rb₂O, and Cs₂O in the glass.

The disclosure also relates, in various aspects, to a consumer electronic product, comprising:
a housing having a front surface, a back surface and side surfaces;
electrical components provided at least partially within the housing, the electrical components including at least a controller, a memory, and a display, the display being provided at or adjacent to the front surface of the housing; and
a cover substrate disposed over the display;
wherein at least a portion of at least one of the housing and the cover substrate comprises a glass-based article disclosed herein.

Additional features and advantages of the disclosure will be set forth in the detailed description which follows, and in part will be readily apparent to those skilled in the art from that description or recognized by practicing the aspects as described herein, including the detailed description which follows, the claims, as well as the appended drawings.

It is to be understood that both the foregoing general description and the following detailed description are merely exemplary and are intended to provide an overview or framework for understanding the nature and character of the disclosure and claims. The accompanying drawings are included to provide a further understanding of the disclosure and are incorporated into and constitute a part of this specification. The drawings illustrate various aspects of the disclosure and together with the description serve to explain the principles and operations of the various aspects.

### BRIEF DESCRIPTION OF THE DRAWINGS

The following detailed description can be further understood when read in conjunction with the following drawings. Whenever possible, the same reference numerals will be used throughout the drawings to refer to the same or like parts. It is to be understood that the figures are not drawn to scale and the size of each depicted component or the relative size of one component to another is not intended to be limiting.

FIG. 1 schematically depicts a cross section of a glass-based article having compressive stress regions according to aspects described and disclosed herein.

FIG. 2A is a plan view of an exemplary electronic device incorporating any of the glass-based articles disclosed herein.

FIG. 2B is a perspective view of the exemplary electronic device of FIG. 2A.

### DETAILED DESCRIPTION

In the following description, whenever a group is described as comprising at least one of a group of elements and combinations thereof, it is understood that the group may comprise, consist essentially of, or consist of any number of those elements recited, either individually or in combination with each other. Similarly, whenever a group is described as consisting of at least one of a group of elements or combinations thereof, it is understood that the group may consist of any number of those elements recited, either individually or in combination with each other.

Where a range of numerical values is recited herein, comprising upper and lower values, unless otherwise stated in specific circumstances, the range is intended to include the endpoints thereof, and all integers and fractions within the range. Further, when an amount, concentration, or other value or parameter is given as a range, one or more ranges, or a list of upper values and lower values, this is to be understood as specifically disclosing all ranges formed from any pair of any upper range limit or value and any lower range limit or value, regardless of whether such pairs are separately disclosed.

If the term “about” is used in describing a value or an end-point of a range, the disclosure should be understood to include the specific value or end-point referred to. As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. It is noted that the terms “substantially” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue. Thus, for example, a glass that is “substantially free” of any specific component (e.g., Al₂O₃, MgO, or any other component) is one in which the component is not actively added or batched into the glass, but may be present in small amounts as a contaminant (e.g., less than 1000, 500, 400, 300, 200, or 100 ppm), or, if actively added or batched, is present in an amount less than 1 wt. % (e.g., or can be specified to be less than 0.5 wt. %, 0.1 wt. %, or 0.05 wt. %), based on total amount of the glass (moles or mass for ppm, and mass for wt. %).

Generally, lithium aluminosilicate glasses have good ion exchangeability, and chemical strengthening processes have been used to achieve high strength and high toughness properties in lithium aluminosilicate glasses. Substituting Al₂O₃ into the silicate glass network increases the interdiffusivity of monovalent cations during ion exchange, and by chemical strengthening in a molten salt bath (e.g., KNO₃ or NaNO₃), glasses with various desirable properties can be achieved, including high strength, high toughness, and high indentation cracking resistance. The stress profiles achieved through chemical strengthening may have a variety of shapes that increase the drop performance, strength, toughness, and other attributes of the glass-based articles.

In some aspects, lithium containing aluminosilicate glasses having a higher Young's modulus are provided herein. The compositions disclosed herein are unique and represent a balance of compositional components that results in a high Young's modulus, as well as after ion exchange a higher compressive stress than other lithium containing aluminosilicates. Through different ion exchange processes, greater central tension (CT), depth of compression (DOC), and high compressive stress (CS) can be achieved.

High Young's modulus glass and glass-ceramic materials are desired for a broad range of applications ranging from handheld devices to memory disks to fibers. High Young's modulus can result in an increase in the frangibility limit of the glass and often also have high fracture toughness values. For applications that require or involve a hard coating disposed on a glass substrate, having a high Young's modulus glass substrate is advantaged because the increase in the substrate modulus generally decreases the bend radius that the coating experiences. This lowers the probability of cracking and delamination of the coating from the substrate.

For glasses, inclusion of a significant amount of high field strength oxides such as MgO, Y₂O₃, La₂O₃, and so forth, may generally result in a high Young's modulus. However, the difficulty with including high amounts of these elements is that they are generally very refractory, and, thus, liquidus temperatures can easily be too high for manufacturing. It was surprisingly discovered herein that a careful balance of compositional components results in ion-exchangeable, Li₂O-containing aluminosilicate compositions having a high Young's modulus values, while still maintaining desired processability parameters. Herein high Young's modulus values are obtained with high MgO contents, such as, for example, at least 8 mol. % or at least 12 mol. %, and in some aspects up to 16 mol. % or up to 20 mol. % or potentially more. Many of the disclosed glasses have liquidus viscosity values are compatible with rolling capability (e.g., >500 P).

As used herein, the term “ion-exchangeable” means that a glass has a composition such that it is capable of undergoing chemical strengthening by way of ion exchange. For example, a glass having an appropriate structure and containing lithium can undergo ion exchange in a molten salt bath containing sodium and/or potassium so as to replace a portion of the lithium with sodium and/or potassium. Similarly, a glass having an appropriate structure and containing sodium can undergo ion exchange in a molten salt bath containing potassium so as to replace a portion of the sodium with potassium. As is known in the art, replacing smaller alkali ions in glass with larger alkali ions results in a compressive stress in the glass, thereby strengthening the glass. An “appropriate structure” in the glass is one that allows such ion exchange to take place so as to result in a compressive stress and associated strengthening of the glass.

Herein, glass compositions are expressed in terms of mol. % amounts of particular components included therein on an oxide bases unless otherwise indicated. Any component having more than one oxidation state may be present in a glass composition in any oxidation state. However, concentrations of such component are expressed in terms of the oxide in which such component is at its lowest oxidation state unless otherwise indicated.

As used herein, the “frangibility limit” refers to the central tension or stored strain energy above which the glass-based article exhibits frangible behavior. “Frangibility” or “frangible behavior” refers to specific fracture behavior when a material is subjected to an impact or insult. As utilized herein, a glass-based article is considered “non-frangible” when it exhibits no branching in a test area as a result of a frangibility test. As utilized herein, a branch originates at the impact point, and a fragment is considered to be within the test area is any part of the fragment extends into the test area. The fragments, bifurcations, and branches are counted based on any 25 mm by 25 mm square centered on the impact point. Thus, a glass-based article is considered non-frangible if it does not show any branching for any 25 mm by 25 mm square centered on the impact point where the breakage is created according to the procedure described below. A glass-based article is considered “borderline frangible” or close to the frangibility limit if a glass-based article shows less than or equal to 5 branches for any 25 mm by 25 mm square centered on the impact point. A glass-based article is considered “frangible” if a glass-based article shows more than 5 branches for any 25 mm by 25 mm square centered on the impact point. In a frangibility test, an impact probe is brought in to contact with the multi-phase glass, with the depth to which the impact probe extends into the multi-phase glass increasing in successive contact iterations. The step-wise increase in depth of the impact probe allows the flaw produced by the impact probe to reach the tension region while preventing the application of excessive external force that would prevent the accurate determination of the frangible behavior of the glass-based article. In aspects, the depth of the impact probe in the multi-phase glass may increase by about 5 μm in each iteration, with the impact probe being removed from contact with the glass-based article between each iteration. The test area is any 25 mm by 25 mm square centered at the impact point. While coatings, adhesive layers, and the like may be used in conjunction with the multi-phase glass described herein, such external restraints are not used in determining the frangibility or frangible behavior of the multi-phase glass. In aspects, a film that does not affect the fracture behavior of the multi-phase glass may be applied to the multi-phase glass prior to the frangibility test to prevent the ejection of fragments from the multi-phase glass.

The term “softening point,” as used herein, refers to the temperature at which the viscosity of the glass composition is 1×10⁷⁰⁶ poise. The softening point was determined using the parallel plate viscosity method of ASTM C1351M-96(2012).

The term “annealing point,” as used herein, refers to the temperature at which the viscosity of the glass composition is 1×10¹³ poise.

The term “strain point,” as used herein, refers to the temperature at which the viscosity of the glass composition is 1×10^{14,68} poise.

As utilized herein, a “glass substrate” refers to a glass piece that has not been ion exchanged. Similarly, a “glass article” refers to a glass piece that has been ion exchanged and is formed by subjecting a glass substrate to an ion exchange process. A “glass-based substrate” and a “glass-based article” are defined accordingly and include glass substrates and glass articles as well as substrates and articles that are made wholly or partly of glass, such as glass substrates that include a surface coating. While glass substrates and glass articles may generally be referred to herein for the sake of convenience, the descriptions of glass substrates and glass articles should be understood to apply equally to glass-based substrates and glass-based articles.

The compositions described herein are selected to achieve a high Young's modulus value and, in some aspects a high fracture toughness value, in either case while also maintaining a desired degree of manufacturability.

In some aspects, the glass compositions disclosed herein comprise one or more of SiO₂, Al₂O₃, MgO, CaO, Na₂O, and Li₂O. In some aspects, the glass compositions disclosed herein comprise SiO₂, Al₂O₃, and MgO. In some aspects, the glass compositions disclosed herein comprise SiO₂, Al₂O₃, MgO, and CaO. In some aspects, the glass compositions disclosed herein comprise SiO₂, Al₂O₃, MgO, and Li₂O. In some aspects, the glass compositions disclosed herein comprise SiO₂, Al₂O₃, CaO, and Li₂O. In some aspects, the glass compositions disclosed herein comprise SiO₂, Al₂O₃, MgO, CaO, and Li₂O. In some aspects, the glass composition disclosed herein comprise SiO₂, Al₂O₃, MgO, Na₂O, and Li₂O.

In some aspects, the glass compositions comprise 62.5-68 mol. % SiO₂; 9.5-16 mol. % Al₂O₃; 12-16 mol. % MgO; 8-11.2 mol. % Li₂O; and less than 0.6 mol. % ZrO₂; wherein R₂O/Al₂O₃ is at least 0.8, amounts are in mol. %, and R₂O is a total amount of Li₂O, Na₂O, K₂O, Rb₂O, and Cs₂O in the glass. In some aspects, the glass compositions comprise 62.5-65.5 mol. % SiO₂; 9.5-12 mol. % Al₂O₃; 12-14 mol. % MgO; 9-11.2 mol. % Li₂O; and less than 0.2 mol. % ZrO₂; wherein R₂O/Al₂O₃ is at least 0.8-2, amounts are in mol. %, and R₂O is a total amount of Li₂O, Na₂O, K₂O, Rb₂O, and Cs₂O in the glass.

In some aspects of the glass compositions described herein, SiO₂ is the largest constituent and, as such, SiO₂ is the primary constituent of the glass network formed from the glass composition. Pure SiO₂ has a relatively low coefficient of thermal expansion (CTE). However, pure SiO₂ has a high melting point. Accordingly, if the concentration of SiO₂ in the glass composition is too high, the formability of the glass composition may be diminished as higher concentrations of SiO₂ increase the difficulty of melting the glass, which, in turn, adversely impacts the formability of the glass. Additionally, the inclusion of too much SiO₂ in the glass composition decreases the capacity of the glass to produce compressive stress through ion exchange. If the concentration of SiO₂ in the glass composition is too low the chemical durability of the glass may be diminished, and the glass may be susceptible to surface damage during post-forming treatments. In some aspects, the glass compositions generally comprise SiO₂ in an amount (mol. %) of at least 55, at least 56, at least 57, at least 58, at least 59, at least 60, at least 60.5, at least 61, at least 61.5, at least 62, at least 62.5, at least 63, at least 63.5, at least 64, at least 64.5, at least 65, at least 65.5, at least 66, at least 66.5, at least 67, at least 67.5, at least 68, at least 68.5, at least 69, at least 69.5, at least 70, at least 71, at least 72, at least 73, at least 74, 74 or less, 73 or less, 72 or less, 71 or less, 70 or less, 69.5 or less, 69 or less, 68.5 or less, 68 or less, 67.5 or less, 67 or less, 66.5 or less, 66 or less, 65.5 or less, 65 or less, 64.5 or less, 64 or less, 63.5 or less, 63 or less, 62.5 or less, 62 or less, 61.5 or less, 61 or less, 60.5 or less, 60 or less, 59 or less, 58 or less, 57 or less, 56 or less, or any range formed therefrom. For example, in some aspects, the glass compositions generally comprise SiO₂ in an amount (mol. %) of 55-74, 55-72, 55-70, 55-68, 55-66, 55-64, 55-62.5, 55-62, 55-60, 55-58, 60-74, 60-72, 60-70, 60-68, 60-66, 60-64, 60-62.5, 61.5-74, 61.5-70, 61.5-68, 61.5-64, 61.5-62, 62-74, 62-70, 62-68, 62-67, 62-66, 62-65, 62-64, 62-63, 62.5-74, 62.5-72, 62.5-70, 62.5-69, 62.5-68, 62.5-67.5, 62.5-66.5, 62.5-66, 62.5-65.5, 62.5-64.5, 63-74, 63-72, 63-70, 63-68, 63-67.5, 63-66.5, 63-65.5, 63-64.5, 63-65.5, 64-74, 64-70, 64-68, 64-66, 66-74, 66-70, 66-68.5, 66-67.5, 67-74, 67-72, 67-70, 67-68, 68-74, 68-72, 68-70, or 70-74.

In some aspects, the glass compositions include Al₂O₃. In some aspects, Al₂O₃ may serve as a glass network former, similar to SiO₂. In some aspects, Al₂O₃ may increase the liquidus viscosity of a glass melt formed from the glass composition due to its tetrahedral coordination, decreasing the formability of the glass composition when the amount of Al₂O₃ is too high. However, when the concentration of Al₂O₃ is balanced against the concentration of SiO₂ and the concentration of alkali oxides in the glass composition, Al₂O₃ can reduce the liquidus temperature of the glass melt, thereby enhancing the liquidus viscosity and improving the compatibility of the glass composition with certain forming processes. An increase in the content of Al₂O₃ relative to the total content of alkali and alkaline earth oxides in the glass composition generally improves the durability of the glass. When the concentration of alkali oxides (R₂O) is close or greater than the amount of Al₂O₃ in the glass composition, predominantly all or all aluminum in the glass is present in tetrahedral coordination state with the alkali ions acting as a charge-compensator. This charge balancing allows for a high diffusivity of alkali ions, increasing the rate of ion exchange. In some aspects, the inclusion of Al₂O₃ in the glass compositions facilitates the high fracture toughness values described herein. In some aspects, the glass compositions comprise Al₂O₃ in an amount (mol. %) of at least 5, at least 7, at least 9, at least 9.5, at least 10, at least 11, at least 12, at least 13, at least 14, at least 15, at least 16, 20 or less, 19 or less, 17 or less, 16 or less, 15 or less, 14 or less, 13 or less, 12 or less, 11 or less, 10 or less, 9.5 or less, or any range formed therefrom. For example, in some aspects, the glass compositions comprise 5-20, 9-17, 9-16, 9-15, 9-14, 9-13, 9-12, 9-11, 9-10, 9-9.5, 9.5-17, 9.5-16, 9.5-15, 9.5-14, 9.5-13, 9.5-12, 9.5-11, 9.5-10, 10-17, 10-16, 10-15, 10-14, 10-13, 10-12, 10-11, 11-17, 11-16, 11-15, 11-14, 11-13, 11-12, 12-17, 12-16, 12-15, 12-14, 12-13, 13-17, 13-16, 13-15, 13-14, 14-17, 14-16, 14-15, 15-17, 15-16, or 16-17. In some aspects, the glass composition is free or substantially free of Al₂O₃.

In some aspects, the glass compositions described herein include MgO. In some aspects, MgO may lower the liquidus viscosity of a glass and improve the melting behavior, which enhances the formability and manufacturability of the glass. In some aspects, the inclusion of MgO in a glass composition may also improve the strain point and the Young's modulus of the glass composition. However, if too much MgO is added to the glass composition, the liquidus viscosity may be too low for compatibility with desirable forming techniques. The addition of too much MgO may also increase the density and the CTE of the glass composition to undesirable levels and reduce the alkali ion mobility in the glass reducing the effectiveness of ion exchange treatments. The inclusion of MgO in the glass composition also helps to facilitate achieving the high fracture toughness values described herein due to the high field strength of MgO. In some aspects, the glass compositions comprise MgO in an amount (mol. %) of at least 8, at least 9, at least 10, at least 11, at least 12, at least 12.5, at least 13, at least 13.5, at least 14, at least 14.5, at least 15, at least 15.5, at least 16, at least 16.5, at least 17, at least 18, at least 19, at least 20, 20 or less, 19 or less, 18 or less, 17 or less, 16.5 or less, 16 or less, 15.5 or less, 15 or less, 14.5 or less, 14 or less, 13.5 or less, 13 or less, 12.5 or less, 12 or less, 11 or less, 10 or less, 9 or less, 8 or less, or any range formed therefrom. For example, in some aspects, the glass compositions comprise MgO in an amount (mol. %) of 8-20, 8-18, 8-16, 8-14, 8-12, 8-10, 10-20, 10-18, 10-16, 10-14, 10-12, 12-20, 12-18, 12-16, 12-15.5, 12-15, 12-14.5, 12-14, 12-13.5, 12-13, 12-12.5, 12.5-20, 12.5-18, 12.5-16, 12.5-15.5, 12.5-15, 12.5-14.5, 12.5-14, 12.5-13.5, 12.5-13, 13-20, 13-18, 13-16, 13-15.5, 13-15, 13-14.5, 13-14, 13-13.5, 13.5-20, 13.5-18, 13.5-16, 13.5-15.5, 13.5-15, 13.5-14.5, 13.5-14, 14-20, 14-18, 14-16, 14-15.5, 14-15, 14-14.5, 14.5-20, 14.5-18, 14.5-16, 14.5-15.5, 14.5-15, 15-20, 15-18, 15-16, 15-15.5, 15.5-20, 15.5-18, 15.5-16, 16-20, 16-18, or 18-20. In some aspects, the glass composition is free or substantially free of MgO.

In some aspects, the glass compositions described herein may include CaO. In some aspects, CaO may lower the liquidus viscosity of a glass, which may enhance the formability, the strain point, and the Young's modulus. However, if too much CaO is added to the glass composition, the density and the CTE of the glass composition may increase to undesirable levels and the ion exchangeability of the glass may be undesirably impeded due to decreased alkali ion mobility. In some aspects, the glass compositions comprise CaO in an amount (mol. %) of at least 5, at least 5.5, at least 6, at least 6.5, at least 7, at least 7.5, at least 8, at least 8.5, at least 9, at least 9.5, at least 10, at least 11, at least 12, at least 13, at least 14, at least 15, at least 16, at least 17, at least 18, at least 19, at least 20, 20 or less, 19 or less, 18 or less, 17 or less, 16 or less, 15 or less, 14 or less, 13 or less, 12 or less, 11 or less, 10 or less, 9.5 or less, 9 or less, 8.5 or less, 8 or less, 7.5 or less, 7 or less, 6.5 or less, 6 or less, 5.5 or less, or any range formed therefrom. For example, in some aspects, the glass compositions comprise CaO in an amount (mol. %) of 5-20, 5-19, 5-18, 5-17, 5-16, 5-15, 5-14, 5-13, 5-12, 5-11, 5-10, 5-9.5, 5-9, 5-8, 5-7, 5-6, 6-20, 6-19, 6-18, 6-15, 6-14, 6-13, 6-12, 6-11, 6-10, 6-9.5, 6-9, 6-8, 6-7, 7-20, 7-15, 7-14, 7-13, 7-12, 7-11, 7-10, 7-9.5, 7-9, 7-8, 8-20, 8-15, 8-14, 8-13, 8-12, 8-11, 8-10, 8-9.5, 8-9, 9-20, 9-15, 9-14, 9-13, 9-12, 9-11, 9-10, 9-9.5, 9.5-20, 9.5-15, 9.5-14, 9.5-13, 9.5-12, 9.5-11, 9.5-10, 10-20, 10-15, 10-14, 10-13, 10-12, 10-11, 11-20, 11-15, 11-14, 11-13, 11-12, 12-20, 12-15, 12-14, 12-13, 13-20, 13-15, 13-14, 14-20, 14-17, 14-15, 15-20, 15-17, or 17-20. In some aspects, the glass composition is substantially free or free of CaO.

In some aspects, the glass compositions include Li₂O. In some aspects, the inclusion of Li₂O in the glass composition allows for better control of an ion exchange process and further reduces the softening point, liquidus temperature, and melting temperature of the glass, thereby increasing the manufacturability of the glass. The presence of Li₂O in the glass compositions also facilitates the formation of a stress profile with a parabolic shape. The Li₂O in the glass compositions also facilitates high fracture toughness values. The inclusion of too much Li₂O in the glass composition increase the coefficient of thermal expansion and lowers the chemical durability of the glass. In some aspects, if insufficient Li₂O is included in the glass composition, the ability of the glass to be ion exchanged is undesirably reduced and the desired stress profile may not be achieved. In some aspects, the glass composition comprises Li₂O in an amount (mol. %) of at least 5, at least 5.5, at least 6, at least 6.5, at least 7, at least 7.5, at least 8, at least 8.5, at least 9, at least 9.5, at least 10, at least 11, at least 11.2, at least 11.3, at least 12, at least 12.5, at least 13, at least 13.5, at least 14, at least 14.5, at least 15, 16 or less, 15 or less, 14.5 or less, 14 or less, 13.5 or less, 13 or less, 12.5 or less, 12 or less, 11.5 or less, 11.3 or less, 11.2 or less, 11 or less, 10.5 or less, 10 or less, 9.5 or less, 9 or less, 8.5 or less, 8 or less, 7.5 or less, 7 or less, 6.5 or less, 6 or less, 5.5 or less, or any range formed therefrom. For example, in some aspects, the glass compositions comprise Li₂O in an amount (mol. %) of 5-16, 5-15, 5-14, 5-13, 5-12, 5-11.5, 5-11.3, 5-11.2, 5-11, 5-10, 5-9.5, 5-9, 5-8.5, 5-7.5, 6-16, 6-15, 6-14, 6-13, 6-12, 6-11, 6-10, 6-9, 6-8, 6-7, 7-16, 7-14, 7-12, 7-10, 7-9, 7-8, 7.5-16, 7.5-15, 7.5-14, 7.5-13, 7.5-12, 7.5-11.5, 7.5-11.3, 7.5-11.2, 7.5-11, 7.5-10, 7.5-9, 7.5-8, 8-16, 8-15, 8-14, 8-13.5, 8-13, 8-12.5, 8-12, 8-11.5, 8-11.3, 8-11.2, 8-11, 8-10.5, 8-10, 8-9.5, 8-9, 8-8.5, 8.5-16, 8.5-15, 8.5-14, 8.5-13, 8.5-12.5, 8.5-12, 8.5-11.5, 8.5-11.3, 8.5-11.2, 8.5-11, 8.5-10.5, 8.5-10, 8.5-9.5, 8.5-9, 9-16, 9-14, 9-12, 9-11.5, 9-11.3, 9-11.2, 9-11, 9-10.5, 9-10, 9-9.5, 9.5-16, 9.5-14, 9.5-12, 9.5-11.5, 9.5-11.3, 9.5-11.2, 9.5-11, 9.5-10.5, 9.5-10, 10-16, 10-15, 10-14, 10-12, 10-11.5, 10-11.3, 10-11.2, 10-11, 10-10.5, 10.5-16, 10.5-15, 10.5-14, 10.5-13, 10.5-12, 10.5-11.5, 10.5-11.3, 10.5-11.2, 10.5-11, 11-16, 11-15, 11-14, 11-13, 11-12, 11-11.5, 11-11.3, 11-11.2, 11.2-16, 11.2-15, 11.2-14, 11.2-13, 11.2-12, 11.2-11.5, 11.5-16, 11.5-15, 11.5-14, 11.5-13, 11.5-12, 12-16, 12-14, or 14-16. In some aspects, the glass composition is substantially free or free of Li₂O.

In some aspects, the glass compositions described herein include Na₂O. In some aspects, Na₂O aids in the ion-exchangeability of the glass composition, and improves the formability, and thereby manufacturability, of the glass composition. However, if too much Na₂O is added to the glass composition, the CTE may be too low. Additionally, if too much Na₂O is included in the glass relative to the amount of Li₂O the ability of the glass to achieve a deep depth of compression when ion exchanged may be reduced. In some aspects, the glass composition comprises Na₂O in an amount (mol. %) of at least 1, at least 2, at least 3, at least 4, at least 5, at least 6, at least 7, at least 8, at least 9, at least 10, 10 or less, 9 or less, 8 or less, 7 or less, 6 or less, 5 or less, 4 or less, 3 or less, 2 or less, 1 or less, or any range formed therefrom. For example, in some aspects, the glass composition comprises Na₂O in an amount (mol. %) of 0-10, 0-9, 0-8, 0-7, 0-6, 0-5, 0-4, 0-3, 0-2, 0-1, >0-10, >0-9, >0-8, >0-7, >0-6, >0-5, >0-4, >0-3, >0-2, >0-1, 1-10, 1-9, 1-8, 1-7, 1-6, 1-5, 1-4, 1-3, 1-2, 2-10, 2-9, 2-8, 2-7, 2-6, 2-5, 2-4, 2-3, 3-10, 3-9, 3-8, 3-7, 3-6, 3-5, 3-4, 4-10, 4-9, 4-8, 4-7, 4-6, 4-5, 5-10, 5-9, 5-8, 5-7, 5-6, 6-10, 6-9, 6-8, 6-7, 7- 10, 7-9, 7-8, 8-10, 8-9, or 9-10. In some aspects, the glass compositions are substantially free or free of Na₂O.

In some aspects, the glass compositions may include one or more fining agents. In some aspects, the fining agent may include, for example, SnO₂. In some aspects, SnO₂ may be present in the glass compositions in an amount (mol. %) of at least 0.01, at least 0.05, at least 0.1, at least 0.15, at least 0.2, at least 0.25, at least 0.3, at least 0.4, at least 0.6, at least 0.8, 1 or less, 0.8 or less, 0.6 or less, 0.4 or less, 0.3 or less, 0.25 or less, 0.2 or less, 0.15 or less, 0.1 or less, 0.05 or less, 0.01 or less, or any range formed therefrom. For example, in some aspects, the glass compositions can comprise SnO₂ in an amount (mol. %) of 0-1, 0-0.8, 0-0.6, 0-0.4, 0-0.3, 0-0.2, 0-0.1, 0-0.05, >0-1, >0-0.8, >0-0.6, >0-0.4, >0-0.3, >0-0.2, >0-0.1, >0-0.05, 0.05-1, 0.05-0.8, 0.05-0.6, 0.05-0.4, 0.05-0.3, 0.05-0.2, 0.05-0.1, 0.1-1, 0.1-0.8, 0.1-0.6, 0.1-0.4, 0.1-0.3, 0.1-0.25, 0.1-0.2, 0.1-0.15, 0.15-1, 0.15-0.8, 0.15-0.6, 0.15-0.4, 0.15-0.3, 0.15-0.25, 0.15-0.2, 0.2-1, 0.2-0.8, 0.2-0.6, 0.2-0.4, 0.2-0.3, 0.2-0.25, 0.25-1, 0.25-0.8, 0.25-0.6, 0.25-0.4, 0.25-0.3, 0.3-1, 0.3-0.8, 0.3-0.6, 0.3-0.4, 0.4-1, 0.4-0.8, 0.4-0.6, 0.6-1, 0.6-0.8, or 0.8-1. In some aspects, the glass composition may be substantially free or free of SnO₂. In some aspects, the glass composition may be free or substantially free of one or both of arsenic and antimony.

In some aspects, the glass compositions comprise a ratio of R₂O/Al₂O₃ of any suitable value, in which the R₂O and Al₂O₃ amounts are in mol. %, and R₂O is a total amount of Li₂O, Na₂O, K₂O, Rb₂O, and Cs₂O in the glass composition. In some aspects, glass compositions comprise a ratio of R₂O/Al₂O₃ of at least 0.4, at least 0.5, at least 0.6, at least 0.7, at least 0.8, at least 0.9, at least 1, at least 1.1, at least 1.2, at least 1.3, at least 1.4, at least 1.5, at least 1.6, at least 1.7, at least 1.8, at least 1.9, 2 or less, 1.9 or less, 1.8 or less, 1.7 or less, 1.6 or less, 1.5 or less, 1.4 or less, 1.3 or less, 1.2 or less, 1.1 or less, 1 or less, 0.9 or less, 0.8 or less, 0.7 or less, 0.6 or less, 0.5 or less, or any range formed therefrom. For example, in some aspects, the glass compositions comprise a ratio of R₂O/Al₂O₃ of 0.4-2, 0.4-1.8, 0.4-1.6, 0.4-1.5, 0.4-1.4, 0.4-1.2, 0.4-1, 0.4-0.8, 0.4-0.6, 0.4-0.5, 0.5-2, 0.5-1.8, 0.5-1.6, 0.5-1.5, 0.5-1.4, 0.5-1.2, 0.5-1, 0.5-0.8, 0.5-0.6, 0.6-2, 0.6-1.8, 0.6-1.6, 0.6-1.5, 0.6-1.4, 0.6-1.2, 0.6-1, 0.6-0.8, 0.6-0.7, 0.7-2, 0.7-1.8, 0.7-1.6, 0.7-1.5, 0.7-1.2, 0.7-1.1, 0.7-0.9, 0.7-0.8, 0.8-2, 0.8-1.8, 0.8-1.6, 0.8-1.4, 0.8-1.2, 0.8-1.1, 0.8-1, 0.8-0.9, 0.9-2, 0.9-1.8, 0.9-1.6, 0.9-1.5, 0.9-1.1, 0.9-1, 1-2, 1-1.8, 1-1.6, 1-1.5, 1-1.4, 1-1.3, 1-1.2, 1-1.1, 1.1-2, 1.1-1.8, 1.1-1.6, 1.1-1.5, 1.1-1.4, 1.1-1.3, 1.1-1.2, 1.2-2, 1.2-1.8, 1.2-1.6, 1.2-1.4, 1.2-1.3, 1.3-2, 1.3-1.8, 1.3-1.7, 1.3-1.6, 1.3-1.5, 1.3-1.4, 1.4-2, 1.4-1.8, 1.4-1.7, 1.4-1.6, 1.4-1.5, 1.5-2, 1.5-1.8, 1.5-1.6, 1.6-1.8, 1.6-1.7, 1.7-2, 1.7-1.8, or 1.8-2.

In some aspects, the glass compositions comprise a ratio of RO/Al₂O₃ of any suitable value, in which the RO and Al₂O₃ amounts are in mol. %, and RO is a total amount of MgO, CaO, SrO, and BaO in the glass composition. In some aspects, the glass compositions comprise a ratio of RO/Al₂O₃ of at least 0.5, at least 0.6, at least 0.7, at least 0.8, at least 0.9, at least 1, at least 1.1, at least 1.2, at least 1.3, at least 1.4, at least 1.5, at least 1.6, at least 1.7, at least 1.8, at least 1.9, at least 2, at least 2.1, at least 2.2, 2.3 or less, 2.2 or less, 2.1 or less, 2 or less, 1.9 or less, 1.8 or less, 1.7 or less, 1.6 or less, 1.5 or less, 1.4 or less, 1.3 or less, 1.2 or less, 1.1 or less, 1 or less, 0.9 or less, 0.8 or less, 0.7 or less, 0.6 or less, or any range formed therefrom. For example, in some aspects, RO/Al₂O₃ is 0.5-2, 0.5-1.8, 0.5-1.6, 0.5-1.4, 0.5-1.3, 0.5-1.2, 0.5-1.1, 0.5-1, 0.5-0.9, 0.5-0.8, 0.5-0.6, 0.6-2, 0.6-1.8, 0.6-1.6, 0.6-1.4, 0.6-1.2, 0.6-1, 0.6-0.8, 0.7-2, 0.7-1.8, 0.7-1.6, 0.7-1.4, 0.7-1.3, 0.7-1.2, 0.7-1.1, 0.7-1, 0.7-0.9, 0.7-0.8, 0.8-2, 0.8-1.8, 0.8-1.6, 0.8-1.4, 0.8-1.2, 0.8-1.1, 0.8-1, 0.8-0.9, 0.9-2, 0.9-1.8, 0.9-1.6, 0.9-1.4, 0.9-1.2, 0.9-1.1, 0.9-1, 1-2, 1-1.8, 1-1.6, 1-1.5, 1-1.4, 1-1.3, 1-1.2, 1-1.1, 1.1-2, 1.1-1.8, 1.1-1.6, 1.1-1.4, 1.1-1.3, 1.1-1.2, 1.2-2, 1.2-1.8, 1.2-1.6, 1.2-1.4, 1.2-1.3, 1.3-2, 1.3-1.8, 1.3-1.6, 1.3-1.5, 1.4-2, 1.4-1.8, 1.4-1.6, 1.6-2, 1.6-1.8, or 1.8-2.

In some aspects, the glass compositions comprise a ratio of (RO+R₂O)/Al₂O₃ of any suitable value, in which the RO, R₂O, and Al₂O₃ amounts are in mol. %, RO is a total amount of MgO, CaO, SrO, and BaO in the glass composition, and R₂O is a total amount of Li₂O, Na₂O, K₂O, Rb₂O, and Cs₂O in the glass composition. Without wishing to be bound by theory, it is believed the ratio (RO+R₂O)/Al₂O₃ is an important indicator of the glass modifiers RO and R₂O are charge compensating for the aluminum in the glass. In this regard, for Al³⁺ to take the place of Si⁴⁺ in a glass structure as a glass former, there needs to be another “charge added to the system so as to balance the charges. While the ions from R₂O are generally more mobile than the ions from RO, RO can still provide charge compensation. Having a appropriate ratio (RO+R₂O)/Al₂O₃ indicates how charged compensated the glass is, and higher ratios generally result in fewer modifiers being locked in the glass network, potentially allowing for easier Li₂O diffusion out of the glass during ion exchange. In some aspects, the glass compositions comprise a ratio of (RO+R₂O)/Al₂O₃ of at least 1, at least 1.1, at least 1.2, at least 1.3, at least 1.4, at least 1.5, at least 1.6, at least 1.7, at least 1.8, at least 1.9, at least 2, at least 2.1, at least 2.2, at least 2.3, at least 2.4, at least 2.5, at least 2.6, at least 2.7, at least 2.8, at least 2.9, at least 3, 3 or less, 2.9 or less, 2.8 or less, 2.7 or less, 2.6 or less, 2.5 or less, 2.4 or less, 2.3 or less, 2.2 or less, 2.1 or less, 2 or less, 1.9 or less, 1.8 or less, 1.7 or less, 1.6 or less, 1.5 or less, 1.4 or less, 1.3 or less, 1.2 or less, 1.1 or less, 1 or less, or any range formed therefrom. For example, in some aspects, (RO+R₂O)/Al₂O₃ is 1-3, 1-2.9, 1-2.7, 1-2.5, 1-2.2, 1-2, 1-1.8, 1-1.6, 1-1.4, 1-1.1, 1.1-3, 1.1-2.8, 1.1-2.6, 1.1-2.5, 1.1-2.4, 1.1-2.3, 1.1-2.1, 1.1-1.9, 1.1-1.8, 1.1-1.6, 1.1-1.4, 1.1-1.2, 1.2-3, 1.2-2.8, 1.2-2.6, 1.2-2.4, 1.2-2.2, 1.2-2, 1.2-1.8, 1.2-1.6, 1.2-1.4, 1.4-3, 1.4-2.6, 1.4-2.2, 1.4-2, 1.4-1.8, 1.4-1.6, 1.6-3, 1.6-2.5, 1.6-2.2, 1.6-2, 1.6-1.8, 1.8-3, 1.8-2.6, 1.8-2.5, 1.8-2.1, 1.8-2, 1.8-1.9, 2-3, 2-2.8, 2-2.6, 2-2.4, 2-2.2, 2.2-3, 2.2-2.8, 2.2-2.6, 2.2-2.4, 2.4-3, 2.4-2.8, 2.4-2.6, 2.6-3, 2.6-2.8, or 2.8-3.

In some aspects, the glass is free or substantially free of at least one of ZrO₂, Y₂O₃, La₂O₃, Na₂O, K₂O, P₂O₅, SrO, and B₂O₃.

In some aspects, the glass comprises ZrO₂ in an amount (mol. %) of 0, >0, at least 0.05, at least 0.1, at least 0.2, at least 0.3, at least 0.4, at least 0.5, at least 0.55, at least 0.6, at least 0.8, at least 1, 1 or less, 0.8 or less, 0.6 or less, 0.55 or less, 0.5 or less, 0.4 or less, 0.3 or less, 0.2 or less, 0.1 or less, 0.05 or less, or any range formed therefrom. For example, in some aspects, the glass comprises ZrO₂ in an amount (mol. %) of 0-1, 0-0.8, 0-0.6, 0-0.55, 0-0.5, 0-0.4, 0-0.3, 0-0.2, 0-0.1, 0-0.05, >0-1, >0-0.8, >0-0.6, >0-0.55, >0-0.5, >0-0.4, >0-0.3, >0-0.2, >0-0.1, >0-0.05, 0.05-1, 0.05-0.8, 0.05-0.6, 0.05-0.55, 0.05-0.5, 0.05-0.4, 0.05-0.3, 0.05-0.2, 0.05-0.1, 0.1-1, 0.1-0.8, 0.1-0.6, 0.1-0.55, 0.1-0.5, 0.1-0.4, 0.1-0.3, 0.1-0.2, 0.2-1, 0.2-0.8, 0.2-0.6, 0.2-0.55, 0.2-0.5, 0.2-0.4, 0.2-0.3, 0.3-1, 0.3-0.8, 0.3-0.6, 0.3-0.55, 0.3-0.5, 0.3-0.4, 0.4-1, 0.4-0.8, 0.4-0.6, 0.4-0.55, 0.4-0.5, 0.5-1, 0.5-0.8, 0.5-0.6, 0.5-0.55, 0.55-1, 0.55-0.8, 0.55-0.6, 0.6-1, 0.6-0.8, or 0.6-0.8. In some aspects, the glass comprises ZrO₂ in an amount (mol. %) of 1 or less, 0.8 or less, 0.6 or less, 0.55 or less, 0.5 or less, 0.4 or less, 0.3 or less, 0.2 or less, 0.1 or less, or 0.05 or less.

The glass compositions described herein have liquidus viscosities that are compatible with manufacturing processes that are especially suitable for forming thin glass sheets. For example, the glass compositions are compatible with traditional forming methods such as float, rolling, or pressing processes. Aspects of the glass-based substrates may be described as fusion-formable (i.e., formable using a fusion draw process). The fusion process uses a drawing tank that has a channel for accepting molten glass raw material. The channel has weirs that are open at the top along the length of the channel on both sides of the channel. When the channel fills with molten material, the molten glass overflows the weirs. Due to gravity, the molten glass flows down the outside surfaces of the drawing tank as two flowing glass films. These outside surfaces of the drawing tank extend down and inwardly so that they join at an edge below the drawing tank. The two flowing glass films join at this edge to fuse and form a single flowing glass-based article. The fusion of the glass films produces a fusion line within the glass-based substrate, and this fusion line allows glass-based substrates that were fusion formed to be identified without additional knowledge of the manufacturing history. The fusion draw method offers the advantage that, because the two glass films flowing over the channel fuse together, neither of the outside surfaces of the resulting glass-based article comes in contact with any part of the apparatus. Thus, the surface properties of the fusion drawn glass-based article are not affected by such contact.

The glass compositions described herein may be selected to have liquidus viscosities that are compatible with fusion draw processes. Thus, the glass compositions described herein are compatible with existing forming methods, increasing the manufacturability of glass-based articles formed from the glass compositions. As used herein, the term “liquidus viscosity” refers to the viscosity of a molten glass at the liquidus temperature, wherein the liquidus temperature refers to the temperature at which crystals first appear as a molten glass cools down from the melting temperature, or the temperature at which the very last crystals melt away as temperature is increased from room temperature. Unless specified otherwise, a liquidus viscosity value disclosed in this application is determined by the following method. First, the liquidus temperature of the glass is measured in accordance with ASTM C829-81 (2015), titled “Standard Practice for Measurement of Liquidus Temperature of Glass by the Gradient Furnace Method.” Next, the viscosity of the glass at the liquidus temperature is measured in accordance with ASTM C965-96 (2012), titled “Standard Practice for Measuring Viscosity of Glass Above the Softening Point”. Unless otherwise specified, the liquidus viscosity and temperature of a glass composition or article is measured before the composition or article is subjected to any ion-exchange process or any other strengthening process. In particular, the liquidus viscosity and temperature of a glass composition or article is measured before the composition or article is exposed to an ion-exchange medium, for example before being immersed in an ion-exchange medium such as a molten salt bath.

In some aspects, the glass compositions disclosed herein have any suitable liquidus temperature. For example, in some aspects, the liquidus temperature (° C.) is at least 1000, at least 1050, at least 1100, at least 1150, at least 1200, at least 1250, at least 1300, at least 1350, at least 1400, at least 1450, 1500 or less, 1450 or less, 1400 or less, 1350 or less, 1300 or less, 1250 or less, 1200 or less, 1150 or less, 1100 or less, 1050 or less, 1000 or less, or any range formed therefrom. For example, in some aspects, the glass compositions have a liquidus temperature (° C.) of 1000-1500, 1000-1450, 1000-1400, 1000-1350, 1000-1300, 1000-1250, 1000-1200, 1000-1150, 1000-1100, 1000-1050, 1050-1500, 1050-1450, 1050-1400, 1050-1350, 1050-1300, 1050-1250, 1050-1200, 1050-1150, 1050-1100, 1100-1500, 1100-1450, 1100-1400, 1100-1350, 1100-1300, 1100-1250, 1100-1200, 1100-1150, 1150-1500, 1150-1450, 1150-1400, 1150-1350, 1150-1300, 1150-1250, 1150-1200, 1200-1500, 1200-1450, 1200-1400, 1200-1350, 1200-1300, 1200-1250, 1250-1500, 1250-1450, 1250-1400, 1250-1350, 1250-1300, 1300-1500, 1300-1450, 1300-1400, 1300-1350, 1350-1500, 1350-1450, 1350-1400, 1400-1500, 1400-1450, or 1450-1500.

In some aspects, the glass compositions disclosed herein have any suitable liquidus viscosity. For example, in some aspects, the liquidus viscosity (poise) is at least 700, at least 750, at least 800, at least 900, at least 1000, at least 1100, at least 1200, at least 1300, at least 1400, at least 1500, at least 1600, at least 1700, at least 1800, at least 1900, 2000 or less, 1900 or less, 1800 or less, 1700 or less, 1600 or less, 1500 or less, 1400 or less, 1300 or less, 1200 or less, 1100 or less, 1000 or less, 900 or less, 800 or less, 750 or less, or any range formed therefrom. For example, in some aspects, the glass compositions have a liquidus viscosity (poise) of 700-2000, 700-1900, 700-1800, 700-1600, 700-1400, 700-1200, 700-1000, 700-800, 750-2000, 750-1800, 750-1600, 750-1400, 750-1200, 750-1100, 750-1000, 750-900, 800-2000, 800-1900, 800-1800, 800-1600, 800-1400, 800-1200, 800-1000, 800-900, 900-2000, 900-1900, 900-1800, 900-1600, 900-1400, 900-1200, 900-1000, 1000-2000, 1000-1900, 1000-1800, 1000-1600, 1000-1400, 1000-1200, 1200-2000, 1200-1900, 1200-1800, 1200-1600, 1200-1400, 1400-2000, 1400-1900, 1400-1800, 1400-1600, 1600-2000, 1600-1900, 1600-1800, 1800-2000, 1800-1900, or 1900-2000.

In some aspects, glass compositions disclosed herein have a high fracture toughness. Without wishing to be bound by any particular theory, the high fracture toughness may impart improved drop performance to the glass compositions. The high fracture toughness of the glass compositions described herein increases the resistance of the glasses to damage and allows a higher degree of stress to be imparted to the glass through ion exchange, as characterized by central tension, without becoming frangible. As utilized herein, the fracture toughness refers to the K_{IC} value as measured by the chevron notched short bar method unless otherwise noted. The chevron notched short bar (CNSB) method utilized to measure the K_{IC} value is disclosed in Reddy, K. P. R. et al, “Fracture Toughness Measurement of Glass and Ceramic Materials Using Chevron-Notched Specimens,” J. Am. Ceram. Soc., 71 [6], C-310-C-313 (1988) except that Y*m is calculated using equation 5 of Bubsey, R. T. et al., “Closed-Form Expressions for Crack-Mouth Displacement and Stress Intensity Factors for Chevron-Notched Short Bar and Short Rod Specimens Based on Experimental Compliance Measurements,” NASA Technical Memorandum 83796, pp. 1-30 (October 1992). Additionally, the K_{IC} values are measured on non-strengthened glass samples, such as measuring the K_{IC} value prior to ion exchanging a glass-based substrate to form a glass-based article. The K_{IC} values discussed herein are reported in MPa·m^{0.5}, unless otherwise noted.

In some aspects, the glass substrate has any suitable fracture toughness (K_{IC}). For example, in some aspects, the K_{IC} values are at least 0.8 MPa·m^{0.5}. In some aspects, the K_{IC} values are less than 1.2 MPa·m^{0.5}. In some aspects, the K_{IC} values (MPa·m^{0.5}) are at least 0.8, at least 0.85, at least 0.9, at least 0.95, at least 1, at least 1.05, at least 1.1, at least 1.15, 1.2 or less, 1.15 or less, 1.1 or less, 1.05 or less, 1 or less, 0.95 or less, 0.9 or less, 0.85 or less, or any range formed therefrom. For example, in some aspects, the K_{IC} values (MPa·m^{0.5}) are 0.8-1.2, 0.8-1.15, 0.8-1.1, 0.8-1.05, 0.8-1, 0.8-0.95, 0.8-0.9, 0.8-0.85, 0.85-1.2, 0.85-1.15, 0.85-1.1, 0.85-1.05, 0.85-1, 0.85-0.95, 0.85-0.9, 0.9-1.2, 0.9-1.15, 0.9-1.1, 0.9-1.05, 0.9-1, 0.9-0.95, 0.95-1.2, 0.95-1.15, 0.95-1.1, 0.95-1.05, 0.95-1, 1-1.2, 1-1.15, 1-1.1, 1-1.05, 1.05-1.12, 1.05-1.15, 1.05-1.1, 1.1-1.2, 1.1-1.15, or 1.15-1.2.

Glass compositions according to embodiments have a high Young's modulus. The high Young's modulus values reduce the stored strain energy present in the glass after ion exchange. As utilized herein, the Young's modulus (E) refers to the value measured by a resonant ultrasonic spectroscopy technique of the general type set forth in ASTM E2001-13, titled “Standard Guide for Resonant Ultrasound Spectroscopy for Defect Detection in Both Metallic and Non-metallic Parts.”

In some aspects, the glass compositions have a Young's modulus of at least 82 GPa. In some aspects, the glass compositions have a Young's modulus of less than 104 GPa. In some aspects, the Young's modulus values (GPa) are at least 82, at least 84, at least 86, at least 88, at least 90, at least 92, at least 94, at least 96, at least 98, at least 100, at least 102, at least 104, 104 or less, 102 or less, 100 or less, 98 or less, 96 or less, 94 or less, 92 or less, 90 or less, 88 or less, 86 or less, 84 or less, or any range formed therefrom. For example, in some aspects, the glass compositions comprise Young's modulus values (GPa) of 82-104, 82-102, 82-100, 82-98, 82-94, 82-92, 82-90, 82-88, 82-84, 84-104, 84-102, 84-100, 84-98, 84-96, 84-94, 84-92, 84-90, 84-88, 84-86, 86-104, 86-102, 86-100, 86-98, 86-96, 86-94, 86-92, 86-90, 86-88, 88-104, 88-102, 88-100, 88-98, 88-96, 88-94, 88-92, 88-90, 90-104, 90-102, 90-100, 90-98, 90-96, 90-94, 90-92, 92-104, 92-102, 92-100, 92-98, 92-96, 92-94, 94-104, 94-102, 94-100, 94-98, 94-96, 96-104, 96-102, 96-100, 96-98, 98-104, 98-102, 98-100, 100-104, 100-102, or 102-104.

In some aspects, the glass compositions described herein may form glass-based articles that exhibit an amorphous microstructure and may be substantially free of crystals or crystallites. In other words, the glass-based articles formed from the glass compositions described herein may exclude glass-ceramic materials. In other aspects, the glass compositions described herein may form glass-based articles that comprise crystals or crystallites, such that the glass-based articles in some aspects include glass-ceramic materials.

Compressive stress layers may be formed in the glass by exposing the glass to one or more ion exchange media. In some aspects, an ion exchange medium may be molten salt bath, such as a bath containing a molten nitrate salt. In some aspects, an ion exchange medium may be a molten salt bath including KNO₃, NaNO₃, or any combination thereof. In some aspects, other sodium and potassium salts may be used in an ion exchange medium, such as, for example sodium or potassium nitrites, phosphates, or sulfates. In some aspects, an ion exchange medium may include lithium salts, such as LiNO₃. An ion exchange medium may additionally include additives commonly included when ion exchanging glass, such as silicic acid. The ion exchange process is applied to a glass-based substrate to form a glass-based article that includes a compressive stress layer extending from a surface of the glass-based article to a depth of compression and a central tension region. The glass-based substrate utilized in an ion exchange process may include any of the glass compositions described herein.

In some aspects, disclosed is a method for ion-exchanging a glass-based substrate in a first molten salt bath to form a glass-based article, wherein the glass-based article comprises a compressive stress layer extending from a surface of the glass-based article to a depth of compression, the glass-based article comprises a central tension region, and the glass-based substrate comprises any of the glass compositions disclosed elsewhere herein. In some aspects, the ion-exchanging further comprises a second molten salt bath after the first molten salt bath.

In some aspects, an ion exchange medium (e.g., a first bath, a second bath, and so forth) comprises at least one of NaNO₃, LiNO₃, and KNO₃. In some aspects, an ion exchange medium comprises NaNO₃ and LiNO₃.

In some aspects, an ion exchange medium comprises NaNO₃. Generally, the sodium in an ion exchange medium exchanges with lithium ions in the glass to produce a compressive stress. In some aspects, an ion exchange medium (e.g., molten salt bath) comprises NaNO₃ in an amount (wt. %) of at least 5, at least 10, at least 15, at least 20, at least 25, at least 30, at least 35, at least 40, at least 45, at least 50, at least 55, at least 60, at least 65, at least 70, at least 75, at least 80, at least 85, at least 90, at least 95, at least 99, 100, 100 or less, 95 or less, 90 or less, 85 or less, 80 or less, 75 or less, 70 or less, 65 or less, 60 or less, 55 or less, 50 or less, 45 or less, 40 or less, 35 or less, 30 or less, 25 or less, 20 or less, 15 or less, 10 or less, 5 or less, or any range formed therefrom. For example, in some aspects, the ion exchange medium comprises NaNO₃ in an amount (wt. %) of 5-100, 5-95, 5-90, 5-85, 5-80, 5-75, 5-70, 5-65, 5-60, 5-55, 5-50, 5-45, 5-40, 5-35, 5-30, 5-25, 5-20, 5-15, 5-10, 10-100, 10-95, 10-90, 10-85, 10-80, 10-75, 10-70, 10-65, 10-60, 10-55, 10-50, 10-45, 10-40, 10-35, 10-30, 10-25, 10-20, 10-15, 15-100, 15-95, 15-90, 15-80, 15-70, 15-60, 15-50, 15-40, 15-30, 15-20, 20-100, 20-90, 20-80, 20-70, 20-60, 20-50, 20-40, 20-30, 30-100, 30-90, 30-80, 30-70, 30-60, 30-50, 30-40, 40-100, 40-90, 40-80, 40-70, 40-60, 40-50, 50-100, 50-90, 50-80, 50-70, 50-60, 60-100, 60-90, 60-80, 60-70, 70-100, 70-90, 70-80, 80-100, 80-90, or 90-100. In some aspects, an ion exchange medium comprises 100 wt. % NaNO₃. Any of the amounts in this paragraph for NaNO₃ can be combined with the amounts set forth in for KNO₃ and/or LiNO₃.

In some aspects, an ion exchange medium comprises KNO₃. Generally, the potassium in an ion exchange medium exchanges with sodium and/or lithium ions in the glass to produce a compressive stress. In some aspects, an ion exchange medium (e.g., molten salt bath) comprises KNO₃ in an amount (wt. %) of at least 5, at least 10, at least 15, at least 20, at least 25, at least 30, at least 35, at least 40, at least 45, at least 50, at least 55, at least 60, at least 65, at least 70, at least 75, at least 80, at least 85, at least 90, at least 95, at least 99, 100, 100 or less, 95 or less, 90 or less, 85 or less, 80 or less, 75 or less, 70 or less, 65 or less, 60 or less, 55 or less, 50 or less, 45 or less, 40 or less, 35 or less, 30 or less, 25 or less, 20 or less, 15 or less, 10 or less, 5 or less, or any range formed therefrom. For example, in some aspects, an ion exchange medium comprises KNO₃ in an amount (wt. %) of 5-100, 5-95, 5-90, 5-85, 5-80, 5-75, 5-70, 5-65, 5-60, 5-55, 5-50, 5-45, 5-40, 5-35, 5-30, 5-25, 5-20, 5-15, 5-10, 10-100, 10-95, 10-90, 10-85, 10-80, 10-75, 10-70, 10-65, 10-60, 10-55, 10-50, 10-45, 10-40, 10-35, 10-30, 10-25, 10-20, 10-15, 15-100, 15-95, 15-90, 15-80, 15-70, 15-60, 15-50, 15-40, 15-30, 15-20, 20-100, 20-90, 20-80, 20-70, 20-60, 20-50, 20-40, 20-30, 30-100, 30-90, 30-80, 30-70, 30-60, 30-50, 30-40, 40-100, 40-90, 40-80, 40-70, 40-60, 40-50, 50-100, 50-90, 50-80, 50-70, 50-60, 60-100, 60-90, 60-80, 60-70, 70-100, 70-90, 70-80, 80-100, 80-90, or 90-100. In some aspects, an ion exchange medium comprises 100 wt. % KNO₃. Any of the amounts in this paragraph for KNO₃ can be combined with the amounts set forth in for NaNO₃ and/or LiNO₃.

In some aspects, an ion exchange medium comprises LiNO₃. Generally, the lithium ions are poisoning ions that can make the resulting glass-based article less frangible while maintaining deeper depths of compression. In some aspects, an ion exchange medium (e.g., molten salt bath) comprises LiNO₃ in an amount (wt. %) of at least 1, at least 2, at least 3, at least 4, at least 5, at least 6, at least 7, at least 8, at least 9, at least 10, at least 15, at least 20, at least 25, at least 30, at least 35, at least 40, at least 45, at least 50, at least 55, at least 60, at least 65, at least 70, at least 75, at least 80, at least 85, at least 90, at least 95, at least 99, 100, 100 or less, 95 or less, 90 or less, 85 or less, 80 or less, 75 or less, 70 or less, 65 or less, 60 or less, 55 or less, 50 or less, 45 or less, 40 or less, 35 or less, 30 or less, 25 or less, 20 or less, 15 or less, 10 or less, 9 or less, 8 or less, 7 or less, 6 or less, 5 or less, 4 or less, 3 or less, 2 or less, 1 or less, or any range formed therefrom. For example, in some aspects, an ion exchange medium comprises LiNO₃ in an amount (wt. %) of 1-10, 1-9, 1-8, 1-7, 1-6, 1-5, 1-4, 1-3, 1-2, 2-10, 2-9, 2-8, 2-7, 2-6, 2-5, 2-4, 2-3, 3-10, 3-9, 3-8, 3-7, 3-6, 3-5, 3-4, 4-10, 4-9, 4-8, 4-7, 4-6, 4-5, 5-10, 5-9, 5-8, 5-7, 5-6, 6-10, 6- 9, 6-8, 6-7, 7-10, 7-9, 7-8, 8-10, 8-9, 9-10, 1-100, 5-100, 5-95, 5-90, 5-85, 5-80, 5-75, 5-70, 5-65, 5-60, 5-55, 5-50, 5-45, 5-40, 5-35, 5-30, 5-25, 5-20, 5-15, 5-10, 10-100, 10-95, 10-90, 10-85, 10-80, 10-75, 10-70, 10-65, 10-60, 10-55, 10-50, 10-45, 10-40, 10-35, 10-30, 10-25, 10-20, 10-15, 15-100, 15-95, 15-90, 15-80, 15-70, 15-60, 15-50, 15-40, 15-30, 15-20, 20-100, 20-90, 20-80, 20-70, 20-60, 20-50, 20-40, 20-30, 30-100, 30-90, 30-80, 30-70, 30-60, 30-50, 30-40, 40-100, 40-90, 40-80, 40-70, 40-60, 40-50, 50-100, 50-90, 50-80, 50-70, 50-60, 60-100, 60-90, 60-80, 60-70, 70-100, 70-90, 70-80, 80-100, 80-90, or 90-100. Any of the amounts in this paragraph for LiNO₃ can be combined with the amounts set forth in for NaNO₃ and/or KNO₃.

In some aspects, as discussed elsewhere herein, an ion exchange medium (e.g., molten salt bath) comprises a mixture of Li, Na, and K ions, which can be as nitrate salts. For example, in some aspects, an ion exchange medium comprises 1 wt. % LiNO₃ and 99 wt. % NaNO₃, 2 wt. % LiNO₃ and 98 wt. % NaNO₃, 3 wt. % LiNO₃ and 97 wt. % NaNO₃, 4 wt. % LiNO₃ and 96 wt. % NaNO₃, 5 wt. % LiNO₃ and 95 wt. % NaNO₃, 6 wt. % LiNO₃ and 94 wt. % NaNO₃, 7 wt. % LiNO₃ and 93 wt. % NaNO₃, or 8 wt. % LiNO₃ and 92 wt. % NaNO₃. Further, KNO₃ can be added, in place of LiNO₃ or in addition by replacing an equal portion of NaNO₃.

In some aspects, a glass substrate comprising any of the glass compositions disclosed herein may be exposed to an ion exchange medium by dipping the glass substrate into a bath of the ion exchange medium, spraying the ion exchange medium onto a glass substrate, or otherwise physically applying the ion exchange medium to a glass substrate, thereby forming the ion exchanged glass-based article.

In some aspects, the temperature of an ion exchange medium is any suitable temperature. For example, in some aspects, the temperature (° C.) is at least 400, at least 410, at least 420, at least 430, at least 440, at least 450, at least 460, at least 470, at least 480, at least 490, at least 500, at least 510, at least 520, at least 530, at least 540, at least 550, 550 or less, 540 or less, 530 or less, 520 or less, 510 or less, 500 or less, 490 or less, 480 or less, 470 or less, 460 or less, 450 or less, 440 or less, 430 or less, 420 or less, 410 or less, 400 or less, or any range formed therefrom. For example, in some aspects, the temperature (° C.) is 400-550, 400-520, 400-500, 400-480, 400-460, 400-440, 400-420, 420-550, 420-540, 420-520, 420-500, 420-480, 420-450, 420-440, 420-430, 430-550, 430-540, 430-520, 430-500, 430-480, 430-460, 430-440, 440-550, 440-530, 440-510, 440-500, 440-490, 440-470, 440-450, 450-550, 450-530, 450-500, 450-490, 450-480, 450-460, 460-550, 460-540, 460-520, 460-500, 460-480, 460-470, 470-550, 470-530, 470-500, 470-490, 470-480, 480-550, 480-540, 480-520, 480-500, 480-490, 490-550, 490-540, 490-520, 490-500, 500-550, 500-540, 500-520, 500-510, 510-550, 510-540, 510-530, 510-520, 520-550, 520-540, 520-530, 530-550, 530-540, or 540-550.

In some aspects, ion exchanging a glass substrate in an ion exchange medium takes place for any suitable time period. For example, the time period (hr) is at least 1, at least 2, at least 4, at least 6, at least 8, at least 9, at least 10, at least 12, at least 14, at least 16, at least 18, at least 20, at least 22, at least 24, at least 25, at least 26, at least 28, at least 30, at least 32, at least 34, at least 36, at least 38, at least 40, at least 42, at least 44, at least 46, at least 48, at least 50, 50 or less, 48 or less, 46 or less, 44 or less, 42 or less, 40 or less, 38 or less, 36 or less, 34 or less, 32 or less, 30 or less, 28 or less, 26 or less, 25 or less, 24 or less, 22 or less, 20 or less, 18 or less, 16 or less, 14 or less, 12 or less, 10 or less, 9 or less, 8 or less, 6 or less, 4 or less, 2 or less, or any range formed therefrom. For example, in some aspects, the time period (hr) is 1-50, 1-48, 1-40, 1-36, 1-30, 1-26, 1-18, 1-16, 1-9, 1-4, 4-48, 4-44, 4-40, 4-36, 4-30, 4-25, 4-20, 4-16, 4-12, 4-9, 4-6, 6-48, 6-42, 6-40, 6-36, 6-32, 6-30, 6-28, 6-25, 6-20, 6-16, 6-10, 8-48, 8-40, 8-36, 8-30, 8-25, 8-20, 8-14, 12-48, 12-40, 12-32, 12-24, 12-20, 12-16, 16-48, 16-40, 16-34, 16-30, 16-25, 20-48, 20-40, 20-36, 20-25, 22-48, 22-40, 22-36, 22-32, 22-30, 22-26, 24-48, 24-46, 24-40, 24-38, 24-30, 24-26, 26-48, 26-40, 26-30, 26-28, 30-48, 30-40, 30-38, 30-32, 32-48, 32-46, 32-40, 32-38, 32-34, 34-48, 34-40, 34-38, 38-48, 38-46, 38-40, 40-50, 40-48, 40-46, 40-44, 40-42, or 44-48.

In some aspects, ion exchanging may include a second ion exchange treatment in an ion exchange medium. In some aspects, the second ion exchange treatment can comprise any of the ion exchange media disclosed elsewhere herein (e.g., with respect to composition, temperature, and time), and the conditions can be the same or different from the first ion exchange treatment. In some aspects, the second ion exchange treatment is conducted at a lower temperature than the first ion exchange treatment which, in some aspects, imparts a compressive stress spike at the surface of the glass-based article. In some aspects, the second molten salt bath comprises NaNO₃, KNO₃, or a combination thereof.

In some aspects, the ion exchange process may be performed in an ion exchange medium under processing conditions that provide an improved compressive stress profile as disclosed, for example, as disclosed in U.S. Patent Application Publication No. 2016/0102011, which is incorporated herein by reference in its entirety. In some aspects, the ion exchange process may be selected to form a parabolic stress profile in the glass-based articles, such as those stress profiles described in U.S. Patent Application Publication No. 2016/0102014, which is incorporated herein by reference in its entirety.

After an ion exchange process is performed, it should be understood that a composition at the surface of an ion exchanged glass-based article is different than the composition of the as-formed glass substrate (i.e., the glass substrate before it undergoes an ion exchange process). This results from one type of alkali metal ion in the as-formed glass substrate, such as, for example Li⁺ or Na⁺, being replaced with larger alkali metal ions, such as, for example Na⁺ and/or K⁺ in the case of Li⁺, and K⁺ in the case of Nat. However, the glass composition at or near the center of the depth of the glass-based article generally will, in aspects, still have the composition of the as-formed non-ion exchanged glass substrate utilized to form the glass-based article. This is because, in some aspects, ion exchange generally does not occur at the center of the glass-based article under typical ion exchange conditions employed for strengthening glass-based substrates. Accordingly, a composition at a center of the glass-based articles disclosed herein can be any of the glass compositions disclosed elsewhere herein (e.g., comprising SiO₂, Al₂O₃, MgO, CaO, Na₂O, Li₂O, SnO₂, or any combination thereof, in any of the amounts and/or ratios disclosed herein for such components). Similarly, the properties of a glass having the same composition and microstructure as the composition at the center of a glass-based article can be any of the properties disclosed elsewhere herein for glass compositions (e.g., Young's modulus, fracture toughness, liquidus temperature, liquidus viscosity, etc.). As utilized herein, the center of the glass-based article refers to any location in the glass-based article that is a distance of at least 0.5t from every surface thereof, where t is the thickness of the glass-based article. Generally, the center of the glass-based article is at 0.5t from each of the two major surfaces.

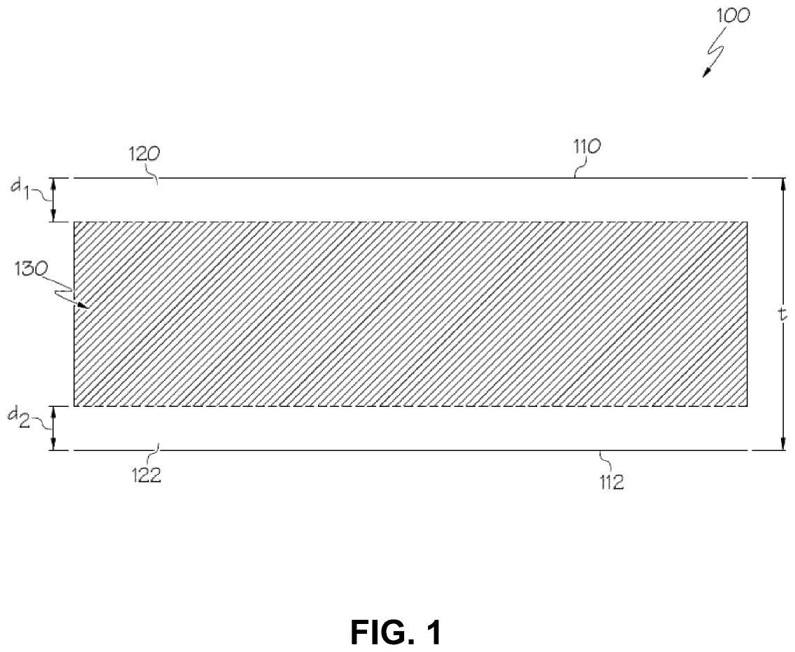

As mentioned elsewhere herein, the glass compositions described herein can be strengthened, such as by ion exchange, making a glass-based article that is damage resistant for applications such as, but not limited to, display covers or housings (e.g., for consumer electronic devices). With reference to FIG. 1, a glass-based article is depicted that has a first region under compressive stress (e.g., first and second compressive layers 120, 122 in FIG. 1) extending from the surface to a depth of compression (DOC) of the glass-based article and a second region (e.g., central region 130 in FIG. 1) under a tensile stress or central tension (CT) extending from the DOC into the central or interior region of the glass-based article. As used herein, DOC refers to the depth at which the stress within the glass-based article changes from compressive to tensile. At the DOC, the stress crosses from a positive (compressive) stress to a negative (tensile) stress and thus exhibits a stress value of zero.

According to the convention normally used in the art, compression or compressive stress is expressed as a negative (<0) stress and tension or tensile stress is expressed as a positive (>0) stress. Throughout this description, however, CS is expressed as a positive or absolute value—i.e., as recited herein, CS=|CS|. The compressive stress (CS) has a maximum at or near the surface of the glass-based article, and the CS varies with distance d from the surface according to a function. Referring again to FIG. 1, a first segment 120 extends from first surface 110 to a depth d₁ and a second segment 122 extends from second surface 112 to a depth d₂. Together, these segments define a compression or CS of glass-based article 100. The surface compressive stress (CS) may be measured using a scattered light polariscope (SCALP) technique or a refractive near field (RNF) technique known in the art. CS values provided herein are measured using a SCALP technique, unless otherwise specified. As used herein, the term “CSₖ” refers to the compressive stress at the depth of the knee (i.e., transition point) as measured by RNF.

The compressive stress of both major surfaces (110, 112 in FIG. 1) is balanced by stored tension in the central region (130) of the glass-based article. The surface compressive stress (CS), maximum central tension (CT) and DOC values may be measured using a scattered light polariscope (SCALP) technique or a refractive near field (RNF) technique known in the art. The SCALP method or RNF method also may be used to determine the stress profile of the glass-based articles.

In some aspects, a compressive stress layer of a glass-based article comprises any suitable compressive stress. For example in some aspects, a compressive stress layer comprises a compressive stress of X MPa at a given depth of compression, or at all depths of compression, of Y, in which X (MPa) is at least 155, at least 160, at least 165, at least 170, at least 175, at least 180, at least 185, at least 190, at least 195, at least 200, at least 205, at least 210, at least 215, at least 220, at least 225, at least 230, at least 235, at least 240, at least 245, at least 250, at least 255, at least 260, at least 265, at least 270, at least 275, at least 280, at least 285, at least 290, at least 295, at least 300, 300 or less, 295 or less, 290 or less, 285 or less, 280 or less, 275 or less, 270 or less, 265 or less, 260 or less, 255 or less, 250 or less, 245 or less, 240 or less, 235 or less, 230 or less, 225 or less, 220 or less, 215 or less, 210 or less, 205 or less, 200 or less, 195 or less, 190 or less, 185 or less, 180 or less, 175 or less, 170 or less, 165 or less, 160 or less, 155 or less, or any range formed therefrom (e.g., a compressive stress (MPa) of 155-300, 155-290, 155-280, 155-270, 155-260, 155-250, 155-240, 155-230, 155-220, 155-210, 155-200, 155-190, 155-180, 155-170, 155-160, 160-300, 160-280, 160-260, 160-240, 160-220, 160-200, 160-180, 180-300, 180-280, 180-260, 180-240, 180-220, 180-200, 190-300, 190-290, 190-270, 190-250, 190-240, 190-220, 190-200, 200-300, 200-285, 200-265, 200-250, 200-230, 200-210, 210-300, 210-290, 210-280, 210-250, 210-240, 210-225, 210-220, 220-300, 220-290, 220-280, 220-260, 220-240, 240-300, 240-260, 260-300, or 280-300), and in which Y is a depth of compression (microns) of at least 0, at least 5, at least 10, at least 15, at least 20, at least 25, at least 30, at least 35, at least 40, at least 45, at least 50, 50 or less, 45 or less, 40 or less, 35 or less, 30 or less, 25 or less, 20 or less, 15 or less, 10 or less, 5 or less, or any range formed therefrom (e.g., a depth of compression (microns) of 0-50, 0-45, 0-40, 0-35, 0-30, 0-25, 0-20, 0-15, 0-10, 0-5, 5-50, 5-45, 5-40, 5-35, 5-30, 5-25, 5-20, 5-15, 5-10, 10-50, 10-45, 10-40, 10-35, 10-30, 10-25, 10-20, 10-15, 15-50, 15-45, 15-40, 15-35, 15-30, 15-25, 15-20, 20-50, 20-45, 20-40, 20-35, 20-30, 20-25, 25-50, 25-45, 25-40, 25-35, 25-30, 30-50, 30-45, 30-40, 30-35, 35-50, 35-45, 35-40, 40-50, 40-50, 40-45, or 45-50). For example, in some aspects, the compressive stress layer can comprise a compressive stress of at least 155 MPa at all depths of compression between 0-45 microns. In some aspects, the compressive stress layer comprises a compressive stress of at least 155 MPa at a depth of compression of at least 10 microns, and some aspects, at all depths of compression between 10 microns and 50 microns.

In some aspects, a compressive stress layer of a glass-based article comprises any suitable maximum surface compressive stress (i.e., at a major surface of the glass-based article). For example, in some aspects, the compressive stress layer comprises a maximum surface compressive stress (MPa) of at least 800, at least 850, at least 900, at least 950, at least 1000, at least 1050, at least 1100, at least 1150, at least 1200, at least 1250, at least 1300, 1300 or less, 1250 or less, 1200 or less, 1150 or less, 1100 or less, 1050 or less, 1000 or less, 950 or less, 900 or less, 850 or less, 800 or less, or any range formed therefrom. For example, in some aspects, the maximum surface compressive stress (MPa) is 800-1300, 800-1250, 800-1200, 800-1150, 800-1100, 800-1050, 800-1000, 800-950, 800-900, 800-850, 850-1300, 850-1250, 850-1200, 850-1150, 850-1100, 850-1050, 850-1000, 850-950, 850-900, 900-1300, 900-1250, 900-1200, 900-1150, 900-1100, 900-1050, 900-1000, 900-950, 950-1300, 950-1250, 950-1200, 950-1150, 950-1100, 950-1050, 950-1000, 1000-1300, 1000-1250, 1000-1200, 1000-1150, 1000-1100, 1000-1050, 1050-1300, 1050-1250, 1050-1200, 1050-1150, 1050-1100, 1100-1300, 1100-1250, 1100-1200, 1100-1150, 1150-1300, 1150-1250, 1150-1200, 1200-1300, 1200-1250, or 1250-1300.

In some aspects, a compressive stress layer of a glass-based article comprises a compressive stress spike extending from the surface of the glass-based article to a depth of compressive stress spike, and the depth of compressive stress spike is any suitable depth. The compressive stress at which the spike transitions from a high slope to a low slope is referred to as the compressive stress at knee (CSₖ), and it is at this CSₖ that the depth is measured from the surface. For example, in some aspects, the depth (microns) is at least 1, at least 1.5, at least 2, at least 2.5, at least 3, at least 3.5, at least 4, at least 4.5, at least 5, at least 5.5, at least 6, at least 6.5, at least 7, at least 7.5, at least 8, at least 8.5, at least 9, at least 9.5, at least 10, 10 or less, 9.5 or less, 9 or less, 8.5 or less, 8 or less, 7.5 or less, 7 or less, 6.5 or less, 6 or less, 5.5 or less, 5 or less, 4.5 or less, 4 or less, 3.5 or less, 3 or less, 2.5 or less, 2 or less, 1.5 or less, 1 or less, or any range formed therefrom. For example, in some aspects, the depth is 1-10, 1-9, 1-8, 1-7, 1-6, 1-5, 1-4, 1-3, 1-2, 2-10, 2-9, 2-8, 2-7, 2-6, 2-5, 2-4, 2-3, 3-10, 3-9, 3-8, 3-7, 3-6, 3-5, 3-4, 4-10, 4-9, 4-8, 4-7, 4- 6, 4-5, 5-10, 5-9, 5-8, 5-7, 5-6, 6-10, 6-9, 6-8, 6-7, 7-10, 7-9, 7-8, 8-10, 8-9, or 9-10.

In some aspects, a tensile stress region of glass-based articles disclosed herein can have any suitable maximum central tension. For example, in some aspects, a tensile stress region of a glass-based article comprises a maximum central tension (MPa) of at least 50, at least 555, at least 60, at least 65, at least 70, at least 75, at least 80, at least 85, at least 90, at least 95, at least 100, at least 105, at least 110, at least 115, at least 120, at least 125, at least 130, at least 135, at least 140, at least 145, at least 150, at least 155, at least 160, at least 165, at least 170, at least 175, at least 180, at least 185, at least 190, at least 195, 200 or less, 195 or less, 190 or less, 185 or less, 180 or less, 175 or less, 170 or less, 165 or less, 160 or less, 155 or less, 150 or less, 145 or less, 140 or less, 135 or less, 130 or less, 125 or less, 120 or less, 115 or less, 110 or less, 105 or less, 100 or less, 95 or less, 90 or less, 85 or less, 80 or less, 75 or less, 70 or less, 65 or less, 60 or less, 55 or less, or any range formed therefrom. For example, the maximum central tension (MPa) can be 50-200, 50-190, 50-180, 50-170, 50-160, 50-150, 50-140, 50-130, 50-120, 50-110, 50-100, 50-90, 50-80, 50-70, 50-60, 60-200, 60-180, 60-160, 60-140, 60-120, 60-100, 60-80, 80-200, 80-180, 80-160, 80-140, 80-120, 80-100, 100-200, 100-180, 100-160, 100-140, 100-120, 120-200, 120-180, 120-160, 120-140, 140-200, 140-180, 140-160, 160-200, 160-180, or 180-200.

In some aspects, a compressive stress layer of a glass-based article comprises a depth of compression (DOC) (microns) of at least 50, at least 55, at least 60, at least 65, at least 70, at least 75, at least 80, at least 85, at least 90, at least 95, at least 100, at least 105, at least 110, at least 115, at least 120, at least 125, 130 or less, 125 or less, 120 or less, 115 or less, 110 or less, 105 or less, 100 or less, 95 or less, 90 or less, 85 or less, 80 or less, 75 or less, 70 or less, 65 or less, 60 or less, 55 or less, or any range formed therefrom. For example, in some aspects, the DOC (microns) of the compressive stress layer is 50-130, 50-120, 50-110, 50-105, 50-95, 50-80, 50-65, 50-55, 55-130, 55-125, 55-115, 55-110, 55-100, 55-95, 55-85, 55-808, 55-75, 55-65, 55-60, 60-130, 60-120, 60-95, 60-85, 60-70, 60-65, 65-130, 65-120, 65-110, 65-100, 65-95, 65-85, 65-70, 70-130, 70-120, 70-100, 70-90, 70-85, 70-75, 75-130, 75-120, 75-100, 75-95, 75-90, 75-80, 90-130, 90-120, 90-100, 100-130, 100-120, 100-110, 110-130, 110-125, 110-115, 115-130, 115-125, 115-120, or 120-130.

In some aspects, the depth of compression (DOC) is provided as a portion of the thickness (t) of the glass-based article. In some aspects, the glass-based articles may have a DOC of at least 0.05t, at least 0.06t, at least 0.08t, at least 0.1t, at least 0.12t, at least 0.14t, at least 0.16t, at least 0.18t, at least 0.2t, at least 0.22t, at least 0.24t, at least 0.25t, 0.25t or less, 0.24t or less, 0.22t or less, 0.2t or less, 0.18t or less, 0.16t or less, 0.14t or less, 0.12t or less, 0.1t or less, 0.08t or less, 0.06t or less, or any range formed therefrom. For example, in some aspects the DOC as a fraction of t is 0.05-0.25, 0.05-0.24, 0.05-0.22, 0.05-0.2, 0.05-0.18, 0.05-0.16, 0.05-0.14, 0.05-0.12, 0.05-0.1, 0.05-0.08, 0.05-0.06, 0.06-0.25, 0.06-0.24, 0.06-0.22, 0.06-0.2, 0.06-0.18, 0.06-0.16, 0.06-0.14, 0.06-0.12, 0.06-0.1, 0.06-0.08, 0.08-0.25, 0.08-0.24, 0.08-0.22, 0.08-0.2, 0.08-0.18, 0.08-0.16, 0.08-0.14, 0.08-0.12, 0.08-0.1, 0.1-0.25, 0.1-0.24, 0.1-0.22, 0.1-0.2, 0.1-0.18, 0.1-0.16, 0.1-0.14, 0.1-0.12, 0.12-0.25, 0.12-0.24, 0.12-0.22, 0.12-0.2, 0.12-0.18, 0.12-0.16, 0.12-0.14, 0.14-0.25, 0.14-0.24, 0.14-0.22, 0.14-0.2, 0.14-0.18, 0.14-0.16, 0.16-0.25, 0.16-0.24, 0.16-0.22, 0.16-0.2, 0.16-0.18, 0.18-0.25, 0.18-0.24, 0.18-0.22, 0.18-0.2, 0.2-0.25, 0.2-0.24, 0.2-0.22, 0.22-0.25, 0.22-0.24, or 0.24-0.25. As used herein, the DOC can also be expressed as DOC/t (where both DOC and t have the same unit, such as both microns or both millimeters), in which any of the numerical values preceding t in this paragraph are equal to DOC/t via simple algebra.

In some aspects, a glass-based article has any suitable thickness (t). For example, in some aspects, the thickness t (mm) of a glass-based article is at least 0.2, at least 0.3, at least 0.4, at least 0.5, at least 0.6, at least 0.7, at least 0.8, at least 0.9, at least 1, at least 1.2, at least 1.4, at least 1.6, at least 1.8, at least 2, 2 or less, 1.8 or less, 1.6 or less, 1.4 or less, 1.2 or less, 1 or less, 0.9 or less, 0.8 or less, 0.7 or less, 0.6 or less, 0.5 or less, 0.4 or less, 0.3 or less, 0.2 or less, or any range formed therefrom. For example, in some aspects, the thickness t (mm) of a glass-based article is 0.2-2, 0.2-1.8, 0.2-1.6, 0.2-1.4, 0.2-1.2, 0.2-1, 0.2-0.8, 0.2-0.6, 0.2-0.5, 0.2-0.3, 0.3-2, 0.3-1.8, 0.3-1.6, 0.3-1.4, 0.3-1, 0.3-0.9, 0.3-0.7, 0.3-0.5, 0.3-0.4, 0.4-2, 0.4-1.8, 0.4-1.6, 0.4-1.4, 0.4-1.2, 0.4-1, 0.4-0.9, 0.4-0.7, 0.4-0.5, 0.5-2, 0.5-1.8, 0.5-1.2, 0.5-1, 0.5-1.9, 0.5-1.7, 0.5-1.6, 0.6-2, 0.6-1.8, 0.6-1.6, 0.6-1.2, 0.6-1, 0.6-0.9, 0.6-0.7, 0.7-2, 0.7-1.8, 0.7-1.4, 0.7-1.2, 0.7-0.9, 0.7-0.8, 0.8-2, 0.8-1.6, 0.8-1.2, 0.8-0.9, 0.9-2, 0.9-1.6, 0.9-1.2, 0.9-1, 1-2, 1-1.8, 1-1.6, 1-1.4, 1-1.2, 1.2-2, 1.2-1.8, 1.2-1.6, 1.2-1.4, 1.4-2, 1.4-1.8, 1.4-1.6, 1.6-2, 1.6-1.8, or 1.8-2.

In some aspects, Na⁺ and K⁺ ions are exchanged into the glass-based article and the Na⁺ ions diffuse to a deeper depth into the glass-based article than the K⁺ ions. The depth of penetration of K⁺ ions (“Potassium DOL”) is distinguished from DOC because it represents the depth of potassium penetration as a result of an ion exchange process. The Potassium DOL is typically less than the DOC for the articles described herein. Potassium DOL may be measured using a surface stress meter such as the commercially available FSM-6000 surface stress meter, manufactured by Orihara Industrial Co., Ltd. (Japan), which relies on accurate measurement of the stress optical coefficient (SOC). The potassium DOL may define a depth of a compressive stress spike (DOLsP), where a stress profile transitions from a steep spike region to a less-steep deep region. The deep region extends from the bottom of the spike to the depth of compression. The DOLsP of the glass-based articles may be from greater than or equal to 3 μm to less than or equal to 10 μm, such as greater than or equal to 4 μm to less than or equal to 9 μm, greater than or equal to 5 μm to less than or equal to 8 μm, greater than or equal to 6 μm to less than or equal to 7 μm, and all ranges and sub-ranges between the foregoing values.

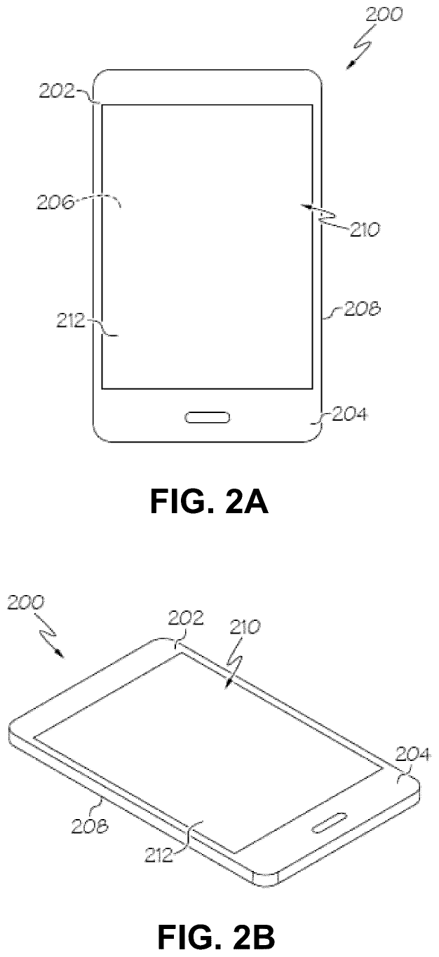

In some aspects, the glass-based articles disclosed herein may be incorporated into another article such as an article with a display (or display articles) (e.g., consumer electronics, including mobile phones, tablets, computers, navigation systems, and the like), architectural articles, transportation articles (e.g., automobiles, trains, aircraft, sea craft, etc.), appliance articles, or any article that requires some transparency, scratch-resistance, abrasion resistance or a combination thereof. An exemplary article incorporating any of the glass-based articles disclosed herein is shown in FIGS. 2A and 2B. Specifically, FIGS. 2A and 2B show a consumer electronic device 200 including a housing 202 having front 204, back 206, and side surfaces 208; electrical components (not shown) that are at least partially inside or entirely within the housing and including at least a controller, a memory, and a display 210 at or adjacent to the front surface of the housing; and a cover 212 at or over the front surface of the housing such that it is over the display. In some aspects, at least a portion of at least one of the cover 212 and the housing 202 may include any of the glass-based articles described herein.

Various aspects are contemplated herein, several of which are set forth in the paragraphs below. It is explicitly contemplated that any aspect or portion thereof can be combined to form a combination.

Aspect 1: A glass, comprising:
62.5-68 mol. % SiO₂;
9.5-16 mol. % Al₂O₃;
12-16 mol. % MgO;
8-11.2 mol. % Li₂O; and
less than 0.6 mol. % ZrO₂;
wherein R₂O/Al₂O₃ is at least 0.8, amounts are in mol. %, and R₂O is a total amount of Li₂O, Na₂O, K₂O, Rb₂O, and Cs₂O in the glass.

Aspect 2: The glass of aspect 1, or any preceding aspect, comprising 62.5-65.5 mol. % SiO₂.

Aspect 3: The glass of aspect 1 or 2, or any preceding aspect, comprising 9.5-12 mol. % Al₂O₃.

Aspect 4: The glass of any one of aspects 1-3, or any preceding aspect, comprising 12-14 mol. % MgO.

Aspect 5: The glass of any one of aspects 1-4, or any preceding aspect, comprising 12.5-13.5 mol. % MgO.

Aspect 6: The glass of any one of aspects 1-5, or any preceding aspect, comprising 9-11.2 mol. % Li₂O.

Aspect 7: The glass of any one of aspects 1-6, or any preceding aspect, comprising >0-1 mol. % SnO₂.

Aspect 8: The glass of any one of aspects 1-7, or any preceding aspect, wherein R₂O/Al₂O₃ is 0.8-2:

Aspect 9: The glass of any one of aspects 1-8, or any preceding aspect, comprising at least one of:
RO/Al₂O₃ of 0.7-2;
(RO+R₂O)/Al₂O₃ is 1.1-3;
wherein amounts are in mol. %, R₂O is a total amount of Li₂O, Na₂O, K₂O, Rb₂O, and Cs₂O in the glass, and RO is a total amount of MgO, CaO, SrO, and BaO in the glass.

Aspect 10: The glass of any one of aspects 1-9, or any preceding aspect, wherein the glass is substantially free of at least one of ZrO₂, Y₂O₃, La₂O₃, Na₂O, K₂O, P₂O₅, SrO, and B₂O₃.

Aspect 11: The glass of any one of aspects 1-10, or any preceding aspect, comprising a Young's modulus of 82-104 GPa.

Aspect 12: The glass of any one of aspects 1-11, or any preceding aspect, comprising a liquidus temperature of 1150-1450° C.

Aspect 13: The glass of any one of aspects 1-12, or any preceding aspect, comprising a liquidus viscosity of 750-2000 poise.

Aspect 14: A method for ion-exchanging a glass-based substrate, the method comprising:
ion-exchanging the glass-based substrate in a first molten salt bath to form a glass-based article,
wherein the glass-based article comprises a compressive stress layer extending from a surface of the glass-based article to a depth of compression, the glass-based article comprises a central tension region, and the glass-based substrate comprises the glass of any one of aspects 1-13, or any preceding aspect.

Aspect 15: The method of aspect 14, or any preceding aspect, wherein the first molten salt bath comprises NaNO₃.

Aspect 16: The method of aspect 14 or 15, or any preceding aspect, wherein the first molten salt bath comprises NaNO₃ and LiNO₃.

Aspect 17: The method of aspect 14 or 15, or any preceding aspect, wherein the first molten salt bath comprises 100 wt. % NaNO₃.

Aspect 18: The method of any one of aspects 14-16, or any preceding aspect, wherein the first molten salt bath comprises KNO₃.

Aspect 19: The method of any one of aspects 14-18, or any preceding aspect, wherein the first molten salt bath is at a temperature of 400-550° C.

Aspect 20: The method of any one of aspects 14-19, or any preceding aspect, wherein the ion-exchanging extends for a time period of 1-48 hours.

Aspect 21: The method of any one of aspects 14-20, or any preceding aspect, wherein the ion-exchanging further comprises a second molten salt bath after the first molten salt bath.

Aspect 22: The method of aspect 21, or any preceding aspect, wherein the second molten salt bath is at a temperature lower than the first molten salt bath.

Aspect 23: The method of aspect 21 or 22, or any preceding aspect, wherein the second molten salt bath comprises NaNO₃, KNO₃, or a combination thereof.

Aspect 24: A glass-based article, comprising:
a compressive stress layer extending from a surface of the glass-based article to a depth of compression;
a central tension region; and
a composition at a center of the glass-based article comprising:
   62.5-68 mol. % SiO₂;
   9.5-16 mol. % Al₂O₃;
   12-16 mol. % MgO;
   8-11.2 mol. % Li₂O; and
   less than 0.6 mol. % ZrO₂;
   wherein R₂O/Al₂O₃ is at least 0.8, amounts are in mol. %, and R₂O is a total amount of Li₂O, Na₂O, K₂O, Rb₂O, and Cs₂O.

Aspect 25: The glass-based article of aspect 24, or any preceding aspect, wherein the compressive stress layer comprises a compressive stress of at least 155 MPa at a depth of compression of at least 10 microns.

Aspect 26: The glass-based article of aspect 24 or 25, or any preceding aspect, wherein the compressive stress layer comprises a compressive stress of at least 155 MPa at all depths of compression between 0-45 microns.

Aspect 27: The glass-based article of any one of aspects 24-26, or any preceding aspect, wherein the compressive stress layer comprises a maximum surface compressive stress of at least 800 MPa.

Aspect 28: The glass-based article of any one of aspects 24-27, or any preceding aspect, wherein the compressive stress layer comprises a compressive stress spike extending from the surface of the glass-based article to a depth of compressive stress spike, and the depth of compressive stress spike is 2-10 microns.

Aspect 29: The glass-based article of any one of aspects 24-28, or any preceding aspect, wherein the central tension region comprises a maximum central tension of 50-200 MPa.

Aspect 30: The glass-based article of any one of aspects 24-29, or any preceding aspect, wherein the depth of compression is 50-130 microns.

Aspect 31: The glass-based article of any one of aspects 24-30, or any preceding aspect, wherein the depth of compression is 0.05t-0.25t, wherein t is the thickness of the glass-based article.

Aspect 32: The glass-based article of any one of aspects 24-31, or any preceding aspect, wherein the glass-based article has a thickness t of 0.2-2 mm.

Aspect 33: The glass-based article of any one of aspects 24-32, or any preceding aspect, wherein the composition at a center of the glass-based article comprises 62.5-65.5 mol. % SiO₂.

Aspect 34: The glass-based article of any one of aspects 24-33, or any preceding aspect, wherein the composition at a center of the glass-based article comprises 9.5-12 mol. % Al₂O₃.

Aspect 35: The glass-based article of any one of aspects 24-34, or any preceding aspect, wherein the composition at a center of the glass-based article comprises 12-14 mol. % MgO.

Aspect 36: The glass-based article of any one of aspects 24-35, or any preceding aspect, wherein the composition at a center of the glass-based article comprises 12.5-13.5 mol. % MgO.

Aspect 37: The glass-based article of any one of aspects 24-36, or any preceding aspect, wherein the composition at a center of the glass-based article comprises 9-11.2 mol. % Li₂O.

Aspect 38: The glass-based article of any one of aspects 24-37, or any preceding aspect, wherein the composition at a center of the glass-based article comprises >0-1 mol. % SnO₂.

Aspect 39: The glass-based article of any one of aspects 24-38, or any preceding aspect, wherein R₂O/Al₂O₃ in the composition at a center of the glass-based article is 0.8-2:

Aspect 40: The glass-based article of any one of aspects 24-39, or any preceding aspect, wherein the composition at a center of the glass-based article comprises at least one of:
RO/Al₂O₃ of 0.7-2;
(RO+R₂O)/Al₂O₃ is 1.1-3;
wherein amounts are in mol. %, R₂O is a total amount of Li₂O, Na₂O, K₂O, Rb₂O, and Cs₂O in the glass, and RO is a total amount of MgO, CaO, SrO, and BaO in the glass.

Aspect 41: The glass-based article of any one of aspects 24-40, or any preceding aspect, wherein the composition at a center of the glass-based article comprises is substantially free of at least one of ZrO₂, Y₂O₃, La₂O₃, Na₂O, K₂O, P₂O₅, SrO, and B₂O₃.

Aspect 42: The glass-based article of any one of aspects 24-41, or any preceding aspect, wherein a glass having the same composition and microstructure as the composition at the center of the glass-based article has a Young's modulus of 82-104 GPa.

Aspect 43: The glass-based article of any one of aspects 24-42, or any preceding aspect, wherein a glass having the same composition and microstructure as the composition at the center of the glass-based article has a liquidus temperature of 1150-1450° C.

Aspect 44: The glass-based article of any one of aspects 24-43, or any preceding aspect, wherein a glass having the same composition and microstructure as the composition at the center of the glass-based article has a liquidus viscosity of 750-2000 poise.

Aspect 45: The glass-based article of any one of aspects 24-44, or any preceding aspect, wherein the compressive stress layer comprises a compressive stress, and an integration of the compressive stress in MPa from 6 microns (or from 4, 5, 6, 7, 8, 9, 10, 11, 12, 13, 14, or 15 microns) to the depth of compression is at least 10.5

Aspect 46: A consumer electronic product, comprising:
a housing having a front surface, a back surface and side surfaces;
electrical components provided at least partially within the housing, the electrical components including at least a controller, a memory, and a display, the display being provided at or adjacent to the front surface of the housing; and
a cover substrate disposed over the display;
wherein at least a portion of at least one of the housing and the cover substrate comprises the glass-based article of any one of aspects 24-45, or any preceding aspect.

Aspect 47: A combination of any two or more preceding aspects or any portion(s) thereof.

### EXAMPLES

The following examples illustrate non-limiting aspects of the disclosure and are not intended to be limiting on the scope of the disclosure or claims.

### Example 1: This Example Demonstrates Glass Compositions that were Prepared and Analyzed

The glass compositions included the components listed in Table 1 below and were prepared by conventional glass forming methods. In Table 1, all components are in mol %. The liquidus temperature and liquidus viscosity were measured according to the method described herein. The Poisson's ratio (v), the Young's modulus (E), and the shear modulus (G) of the glass compositions were measured by a resonant ultrasonic spectroscopy technique of the general type set forth in ASTM E2001-13, titled “Standard Guide for Resonant Ultrasound Spectroscopy for Defect Detection in Both Metallic and Non-metallic Parts.” The refractive index at 589.3 nm and stress optical coefficient (SOC) of the substrates are also reported in Table 1. The refractive index was measured using a PerkinElmer 950 spectrometer. The SOC was measured according to Procedure C (Glass Disc Method) described in ASTM standard C770-16, entitled “Standard Test Method for Measurement of Glass Stress-Optical Coefficient.” The density of the glass compositions was determined using the buoyancy method of ASTM C693-93(2013).

TABLE 1

| Analyzed (mol %) | A | B | C | D | E | F |
|---|---|---|---|---|---|---|
| SiO₂ | 62.9 | 62.8 | 62.6 | 63.4 | 65.2 | 67.9 |
| Al₂O₃ | 12.0 | 14 | 16 | 10 | 10 | 9.9 |
| MgO | 14.8 | 13.9 | 12.9 | 15.4 | 13.4 | 10.9 |
| Li₂O | 10.1 | 9.2 | 8.3 | 11.2 | 11.2 | 11.1 |
| SnO₂ | 0.1 | 0.1 | 0.1 | 0.1 | 0.1 | 0.1 |
| Sum | 99.9 | 100 | 99.9 | 100.1 | 99.9 | 99.9 |
| R₂O/Al₂O₃ | 0.84 | 0.66 | 0.52 | 1.12 | 1.12 | 1.12 |
| RO/Al₂O₃ | 1.23 | 0.99 | 0.81 | 1.54 | 1.34 | 1.10 |
| (RO + R₂O)/Al₂O₃ | 2.08 | 1.65 | 1.33 | 2.66 | 2.46 | 2.22 |
| Poisson's Ratio (RUS) | 0.231 | 0.229 | 0.233 | 0.228 | 0.225 | 0.217 |
| E (Young's Modulus, GPa, RUS) | 91.6 | 91.5 | 93.0 | 91.0 | 89.3 | 87.2 |
| G (Shear Modulus, GPa, RUS) | 37.2 | 37.2 | 37.7 | 37.0 | 36.5 | 35.8 |
| VFT Viscosity Coefficients | | | | | | |
| A | −1.163 | −1.621 | | −1.438 | −1.547 | −1.966 |
| B | 3210 | 3823.6 | | 3602.5 | 4025.6 | 5201.8 |
| T₀ | 504.8 | 477.5 | | 430.6 | 397.4 | 286.4 |
| Temperature at 200 P (° C.) | 1431 | 1452 | | 1394 | 1444 | 1505 |
| Temperature at 35,000 P (° C.) | 1067 | 1098 | | 1033 | 1058 | 1085 |
| Temperature at 200,000 P (° C.) | 1001 | 1030 | | 965 | 985 | 1002 |
| Liquidus Temperature (° C.) | 1280 | 1315 | | 1255 | 1260 | 1285 |
| Primary Liquidus Phase | Lithium | Lithium | | Lithium | Lithium | Lithium |
| | Aluminum | Aluminum | | Aluminum | Aluminum | Aluminum |
| | Silicate | Silicate | | Silicate | Silicate | Silicate |
| Liquidus Viscosity (P) | 950 | 880 | | 855 | 1318 | 1750 |

### Example 2: In this Example, it is Hypothesized that Ion-Exchanging the Glass Compositions Set

forth in Table 1 of Example 1 at different temperatures and times will result in desirable properties, including desirable compressive stress, maximum central tension, and weight gain. For example, the glass compositions of Table 1 can be prepared into substrates having thicknesses of 0.5 mm or 1 mm and then submerged in one or more molten salt baths at temperatures of 450-540° C. for times of 5-40 hours. The molten salt bath can be 100 wt. % NaNO₃, or can be 95 wt. % NaNO₃ and 5 wt. % LiNO₃. It is believed that the glass-based article will have one or more of: a compressive stress layer having a compressive stress of at least 155 MPa at a depth of compression of at least 10 microns; a compressive stress layer having a compressive stress of at least 155 MPa at all depths of compression between 0-45 microns; a compressive stress layer having a maximum surface compressive stress of at least 800 MPa; a compressive stress layer having a compressive stress spike extending from the surface of the glass-based article to a depth of compressive stress spike with the depth of compressive stress spike being 2-10 microns; a central tension region having a maximum central tension of 50-200 MPa; a depth of compression of 50-130 microns; a depth of compression of 0.05t-0.25t, wherein t is the thickness of the glass-based article.

It will be appreciated that the various disclosed aspects or embodiments may involve particular features, elements or steps that are described in connection with that particular aspect or embodiment. It will also be appreciated that a particular feature, element, or step, although described in relation to one particular aspect or embodiment, may be interchanged or combined with alternate aspects or embodiments in various non-illustrated combinations or permutations.

As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

While various features, elements, or steps of particular aspects or embodiments may be disclosed using the transitional phrase “comprising,” it is to be understood that alternative aspects or embodiments, including those that may be described using the transitional phrases “consisting of” or “consisting essentially of,” are implied. Thus, for example, implied alternative aspects or embodiments to a device that comprises A+B+C include aspects or embodiments where a device consists of A+B+C and aspects or embodiments where a device consists essentially of A+B+C.

References herein to the positions of elements (e.g., “top,” “bottom,” “above,” “below,” “first,” “second,” etc.) are merely used to describe the orientation of various elements in the FIGURES. It should be noted that the orientation of various elements may differ according to other exemplary embodiments, and that such variations are intended to be encompassed by the present disclosure. Moreover, these relational terms are used solely to distinguish one entity or action from another entity or action, without necessarily requiring or implying any actual such relationship or order between such entities or actions.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

As utilized herein, “optional,” “optionally,” or the like are intended to mean that the subsequently described event or circumstance can or cannot occur, and that the description includes instances where the event or circumstance occurs and instances where it does not occur. As used herein, the indefinite articles “a,” “an,” and the corresponding definite article “the” mean “at least one” or “one or more,” unless otherwise specified. It also is understood that the various features disclosed in the specification and the drawings can be used in any and all combinations.

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

Unless otherwise specified, all compositions are expressed in terms of as-batched weight percent (wt. %). As will be understood by those having ordinary skill in the art, various melt constituents (e.g., silicon, alkali- or alkaline-based, boron, etc.) may be subject to different levels of volatilization (e.g., as a function of vapor pressure, melt time and/or melt temperature) during melting of the constituents. As such, the as-batched weight percent values used in relation to such constituents are intended to encompass values within ±0.5 wt. % of these constituents in final, as-melted articles. With the forgoing in mind, substantial compositional equivalence between final articles and as-batched compositions is expected.

It will be apparent to those ordinarily skilled in the art that various modifications and variations can be made to the present disclosure without departing from the spirit and scope of the disclosure. Since modifications combinations, sub-combinations, and variations of the disclosed embodiments incorporating the spirit and substance of the disclosure may occur to persons ordinarily skilled in the art, the disclosure should be construed to include everything within the scope of the appended claims and their equivalents.

What is claimed is:

1. A glass, comprising:
62.5-68 mol. % SiO₂;
9.5-16 mol. % Al₂O₃;
12-16 mol. % MgO;
8-11.2 mol. % Li₂O; and
less than 0.6 mol. % ZrO₂;
wherein R₂O/Al₂O₃ is at least 0.8, amounts are in mol. %, and R₂O is a total amount of Li₂O, Na₂O, K₂O, Rb₂O, and Cs₂O in the glass.

2. The glass of claim 1, comprising:
62.5-65.5 mol. % SiO₂;
9.5-12 mol. % Al₂O₃;
12-14 mol. % MgO
9-11.2 mol. % Li₂O; and
R₂O/Al₂O₃ is 0.8-2.

3. The glass of claim 1, comprising at least one of:
RO/Al₂O₃ of 0.7-2;
(RO+R₂O)/Al₂O₃ is 1.1-3;
wherein amounts are in mol. %, R₂O is a total amount of Li₂O, Na₂O, K₂O, Rb₂O, and Cs₂O in the glass, and RO is a total amount of MgO, CaO, SrO, and BaO in the glass.

4. The glass of claim 1, wherein the glass is substantially free of at least one of ZrO₂, Y₂O₃, Na₂O, K₂O, P₂O₅, SrO, and B₂O₃.

5. The glass of claim 1, comprising a Young's modulus of 82-104 GPa.

6. The glass of claim 1, comprising at least one of:
a liquidus temperature of 1150-1450° C.;
a liquidus viscosity of 750-2000 poise.

7. A method for ion-exchanging a glass-based substrate, the method comprising:
ion-exchanging the glass-based substrate in a first molten salt bath to form a glass-based article,
wherein the glass-based article comprises a compressive stress layer extending from a surface of the glass-based article to a depth of compression, the glass-based article comprises a central tension region, and the glass-based substrate comprises the glass of claim 1.

8. The method of claim 7, wherein the first molten salt bath comprises NaNO₃.

9. The method of claim 7, wherein the first molten salt bath is at a temperature of 400-550° C.

10. The method of claim 7, wherein the ion-exchanging further comprises a second molten salt bath after the first molten salt bath, optionally wherein the second molten salt bath is at a temperature lower than the first molten salt bath.

11. A glass-based article, comprising:
a compressive stress layer extending from a surface of the glass-based article to a depth of compression;
a central tension region; and
a composition at a center of the glass-based article comprising:
62.5-68 mol. % SiO₂;
9.5-16 mol. % Al₂O₃;
12-16 mol. % MgO;
8-11.2 mol. % Li₂O; and
less than 0.6 mol. % ZrO₂;
wherein R₂O/Al₂O₃ is at least 0.8, amounts are in mol. %, and R₂O is a total amount of Li₂O, Na₂O, K₂O, Rb₂O, and Cs₂O.

12. The glass-based article of claim 11, wherein the compressive stress layer comprises a compressive stress of at least 155 MPa at a depth of compression of at least 10 microns.

13. The glass-based article of claim 11, wherein the compressive stress layer comprises a compressive stress of at least 155 MPa at all depths of compression between 0-45 microns.

14. The glass-based article of claim 11, wherein the compressive stress layer comprises a compressive stress spike extending from the surface of the glass-based article to a depth of compressive stress spike, and the depth of compressive stress spike is 2-10 microns.

15. The glass-based article of claim 11, wherein the composition at a center of the glass-based article comprises 62.5-65.5 mol. % SiO₂.

16. The glass-based article of claim 11, wherein the composition at a center of the glass-based article comprises:
9.5-12 mol. % Al₂O₃;
9.5-12 mol. % Al₂O₃;
12-14 mol. % MgO
9-11.2 mol. % Li₂O; and
R₂O/Al₂O₃ is 0.8-2.

17. The glass-based article of claim 11, wherein the composition at a center of the glass-based article comprises at least one of:
RO/Al₂O₃ of 0.7-2;
(RO+R₂O)/Al₂O₃ is 1.1-3;
wherein amounts are in mol. %, R₂O is a total amount of Li₂O, Na₂O, K₂O, Rb₂O, and Cs₂O in the glass, and RO is a total amount of MgO, CaO, SrO, and BaO in the glass.

18. The glass-based article of claim 11, wherein the composition at a center of the glass-based article comprises is substantially free of at least one of ZrO₂, Y₂O₃, Na₂O, K₂O, P₂O₅, SrO, and B₂O₃.

19. The glass-based article of claim 11, wherein a glass having the same composition and microstructure as the composition at the center of the glass-based article has at least one of:
a Young's modulus of 82-104 GPa;
a liquidus temperature of 1150-1450° C.;
a liquidus viscosity of 750-2000 poise.

20. A consumer electronic product, comprising:
a housing having a front surface, a back surface and side surfaces;
electrical components provided at least partially within the housing, the electrical components including at least a controller, a memory, and a display, the display being provided at or adjacent to the front surface of the housing; and
a cover substrate disposed over the display;
wherein at least a portion of at least one of the housing and the cover substrate comprises the glass-based article of claim 11.
